(19) United States
(12) Patent Application Publication
(10) Pub. No.: US 2026/0239979 A1
(43) Pub. Date: Aug. 13, 2026

(54) PACKAGE STRUCTURE AND METHOD OF FORMING THE SAME

(71) Applicant: Taiwan Semiconductor Manufacturing Company Limited, Hsinchu (TW)

(72) Inventors: Sheng-Ta LIN, Gongguan Township (TW); Chung-Yueh PAN, Hsinchu (TW); Han Hsiang LIAO, Hsinchu (TW)

(21) Appl. No.: 19/050,162

(22) Filed: Feb. 11, 2025

(51) Int. Cl. H01L 23/40; H01L 21/50; H01L 23/367; H01L 23/538; H01L 25/07

(52) U.S. Cl. CPC H10W 40/611; H10W 40/22; H10W 70/611; H10W 90/00; H10W 90/401; H10W 95/00

(57) ABSTRACT

A package structure includes a package substrate, a package module on the package substrate, a package lid including a package lid plate portion over the package module, and a package lid foot portion connected to the package lid plate portion and attached to the package substrate, and a fastening member located at a corner of the package module and configured to fasten the package lid plate portion to the package substrate.

### BACKGROUND

Semiconductor package warpage may refer to a deformation or bending of a semiconductor package due to internal or external stresses. Semiconductor package warpage may sometimes occur because of differences in the coefficients of thermal expansion (CTE) between the materials used in the semiconductor package (e.g., silicon die, substrate, mold compound, etc.) and thermal gradients that develop during manufacturing or operation. Semiconductor package warpage may result in the semiconductor package not remaining flat, which may lead to issues with mechanical and thermal connections. Elements in a semiconductor package to mitigate against such warpage is desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to one or more embodiments.

FIG. 1B is a vertical cross-sectional view of a package module in the package structure according to one or more embodiments.

FIG. 1C is a detailed vertical cross-sectional view of the package structure according to one or more embodiments.

FIG. 1D is a top-down view of the package structure according to one or more embodiments.

FIG. 1E is a bottom-up view of the package structure according to one or more embodiments.

FIG. 2A is a vertical cross-sectional view of an intermediate structure including the TIVs on a first carrier substrate (e.g., carrier wafer) according to an embodiment of the present invention.

FIG. 2B is a vertical cross-sectional view of an intermediate structure including the interconnect dies on the first carrier substrate according to an embodiment of the present invention.

FIG. 2C is a vertical cross-sectional view of an intermediate structure including the lower molding material layer according to one or more embodiments.

FIG. 2D is a vertical cross-sectional view of an intermediate structure after polishing (e.g., planarizing) the lower molding material layer according to one or more embodiments.

FIG. 2E is a vertical cross-sectional view of an intermediate structure including the upper RDL structure C according to one or more embodiments.

FIG. 2F is a vertical cross-sectional view of an intermediate structure including the semiconductor dies on the upper RDL structure according to one or more embodiments.

FIG. 2G is a vertical cross-sectional view of an intermediate structure including the package module underfill layer according to one or more embodiments.

FIG. 2H is a vertical cross-sectional view of an intermediate structure including the upper molding material layer according to one or more embodiments.

FIG. 2I is a vertical cross-sectional view of an intermediate structure after polishing (e.g., planarizing) the upper molding material layer according to one or more embodiments.

FIG. 2J is a vertical cross-sectional view of an intermediate structure including a second carrier substrate on the upper molded portion according to one or more embodiments.

FIG. 2K is a vertical cross-sectional view of an intermediate structure including the lower RDL structure A according to one or more embodiments.

FIG. 2L is a vertical cross-sectional view of an intermediate structure on a frame mount according to one or more embodiments.

FIG. 2M is a vertical cross-sectional view of an intermediate structure after removing the second carrier substrate according to one or more embodiments.

FIG. 2N is a vertical cross-sectional view of an intermediate structure after remounting the intermediate structure on the frame mount according to one or more embodiments.

FIG. 2O is a vertical cross-sectional view of an intermediate structure including the package module on the package substrate according to one or more embodiments.

FIG. 2P is a vertical cross-sectional view of an intermediate structure including the package underfill layer according to one or more embodiments.

FIG. 2Q is a vertical cross-sectional view of an intermediate structure including the TIM layer and adhesive layer according to one or more embodiments.

FIG. 2R is a vertical cross-sectional view of an intermediate structure including the package lid according to one or more embodiments.

FIG. 2S is a vertical cross-sectional view of a structure including the fastening member according to one or more embodiments.

FIG. 2T is a vertical cross-sectional view of a structure including the solder balls 181 of the BGA according to one or more embodiments.

FIG. 3 is a flow chart illustrating a method of making the package structure according to one or more embodiments.

FIG. 4 is a top-down view of the package structure having a first alternative configuration according to one or more embodiments.

FIG. 5 is a vertical cross-sectional view of the package structure having a second alternative configuration according to one or more embodiments.

FIG. 6 is a vertical cross-sectional view of the package structure having a third alternative configuration according to one or more embodiments.

FIG. 7 is a vertical cross-sectional view of the package structure having a fourth alternative configuration according to one or more embodiments.

FIG. 8A is a vertical cross-sectional view of the package structure having the fifth alternative configuration according to one or more embodiments.

FIG. 8B is a top-down view of the package structure having the fifth alternative configuration according to one or more embodiments.

FIG. 8C is a perspective view of the package structure having the fifth alternative configuration according to one or more embodiments.

FIG. 9 is a vertical cross-sectional view of the package structure having a sixth alternative configuration according to one or more embodiments.

FIG. 10 is a vertical cross-sectional view of the package structure having a seventh alternative configuration according to one or more embodiments.

FIG. 11 is a vertical cross-sectional view of the package structure having an eighth alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Semiconductor package warpage may lead to assembly defects between the semiconductor package and an external structure. In particular, a warped semiconductor package may not make proper contact with solder pads during reflow soldering, leading to open circuits or weak solder joints. Excessive semiconductor package warpage may also cause bridging (short circuits) or tombstoning of components (e.g., where one end of a surface-mounted component (SMT) lifts from the pad of a printed circuit board (PCB) during a reflow soldering process).

Semiconductor package warpage may also lead to thermal and electrical reliability issues. In particular, semiconductor package warpage may disrupt the thermal interface between the semiconductor package and heat sinks or other cooling mechanisms, reducing thermal performance. Poor physical contact may lead to signal integrity issues due to incomplete or intermittent connections.

Semiconductor package warpage may also induce additional mechanical stresses on the package, substrate, or printed circuit board (PCB) during assembly and operation, potentially causing cracks or delamination. Warped semiconductor packages may be rejected during assembly or fail in final testing, leading to increased production costs.

Semiconductor manufacturers may use various strategies to minimize or control package warpage in semiconductor packages. In particular, manufacturers may choose to use materials with closely matched CTEs to reduce thermal mismatch between the die, substrate, and encapsulation materials. High-modulus substrates, such as BT resin or low-warpage epoxy materials may be used to control package warpage. A balanced stack-up of materials in the package may also be used to minimize stress from asymmetric structures.

Semiconductor manufacturers may also optimize processes to reduce semiconductor package warpage. In particular, the mold compound application and curing process may be used to reduce residual stresses. Carefully designed thermal profiles may also be used during curing and soldering to minimize thermal gradients that cause uneven expansion or contraction. Post-mold annealing or stress-relief processes may also be used to help stabilize the semiconductor package.

Semiconductor manufacturers may also modify a structure of the semiconductor package to control package warpage. In particular, stiffener rings and/or heat spreaders may be incorporated to reduce deformation, especially in large packages. Underfill Materials may also be formed between the package module (e.g., die, interposer module, etc.) and package substrate to distribute stress more evenly.

In response to high performance needed in the artificial intelligence industry, package size has been rapidly increasing. High package warpage may be more severe in large packages. It is desirable to reduce package warpage in large packages.

Recently, graphite thermal interface materials (TIMs) and metal TIMs may be used in lidded packages. Graphite TIMs may be attached to a package module (e.g., semiconductor die, interposer module, etc.) inside the semiconductor package but may have no adhesion to the package lid. Metal TIMs may melt during a high temperature and lose constraint to the semiconductor package lid.

Further, in lidded semiconductor package, the package lid and the package substrate may expand and displace in different directions in high temperatures. Due to this behavior, a package lid may become separated from the package module inside the package. This behavior may cause a heat conduction path to be lost in the semiconductor package during a high temperature, resulting in a reduction in heat dissipation performance. This behavior may also increase a degree of semiconductor package warpage.

At least one embodiment of the present disclosure may include a bolted lid structure. The bolted lid structure may help to reduce semiconductor package warpage, especially semiconductor package warpage in a panel-level package. In particular, the bolted lid structure may help to address the high package warpage and heat dissipation challenges facing advanced packaging having a large size and high power and performance requirements. The bolted lid structure may help to secure a package's heat dissipation performance during high temperature and to control package warpage. The bolted lid structure may be applied to any lidded package including, for example, a lidded package for a chip-on-wafer-on substrate structure, integrated fan-out structure, system on integrated chips structures, etc.

The bolted lid structure may use a fastening member such as a bolt to inhibit deformation of the package lid and/or the package substrate when temperature changes and secure a low degree of package warp. The bolted lid design may provide the benefit of lower package warpage and secure heat dissipation performance during a high temperature.

In the bolted lid structure, one or more bolts may be fastened to the package lid and the package substrate. The location of the bolts may be between package lid foot portion and the package module (e.g., chip on wafer), such that both the package substrate and the package lid may be fixed and contact each other during a high temperature. This design may help to ensure good heat dissipation in the package. Different bolt locations may be designed for better package warpage control, heat dissipation and even optimized reliability.

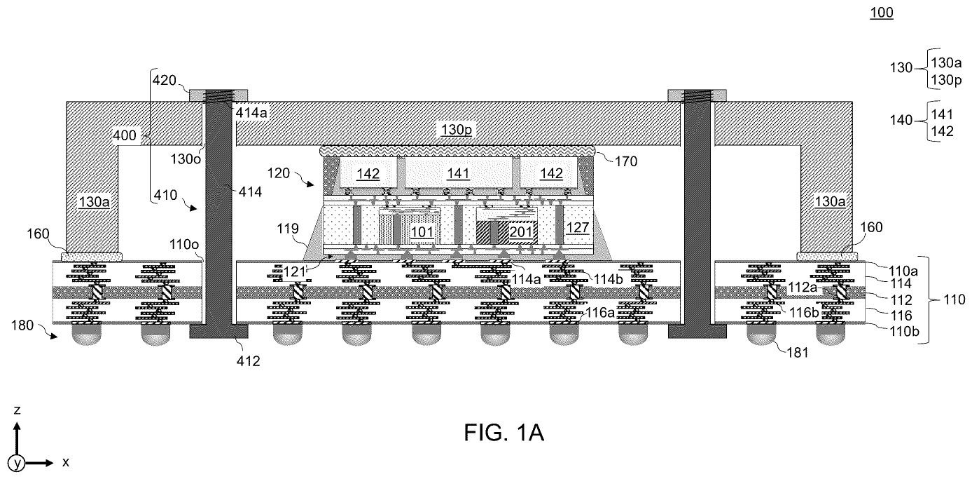

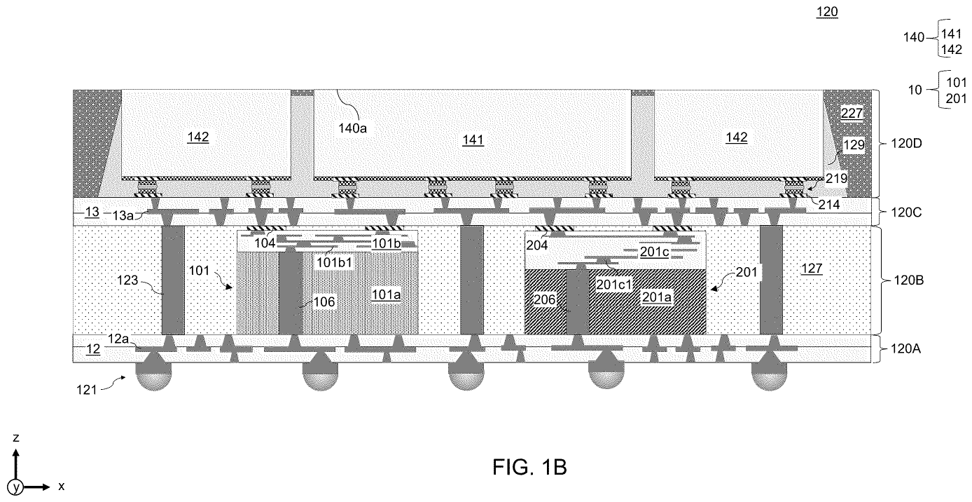

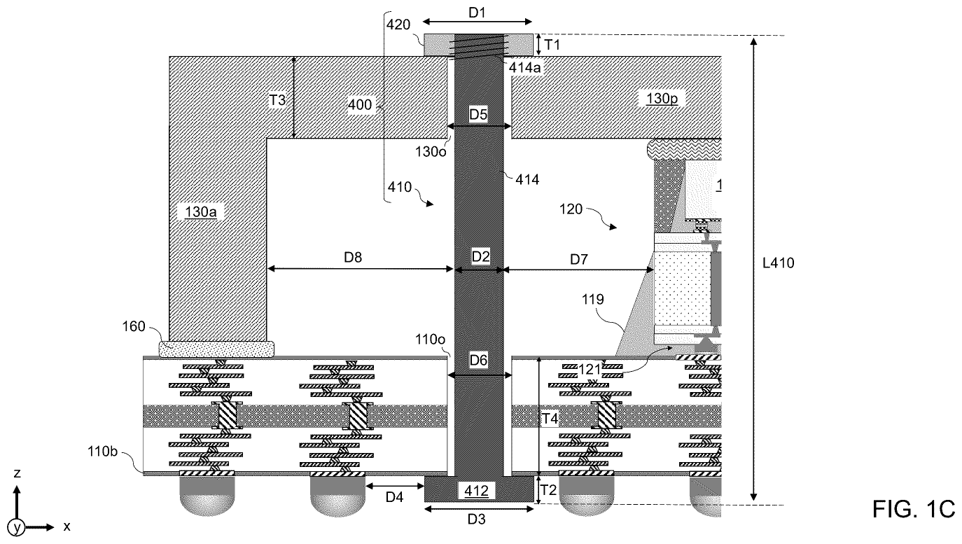

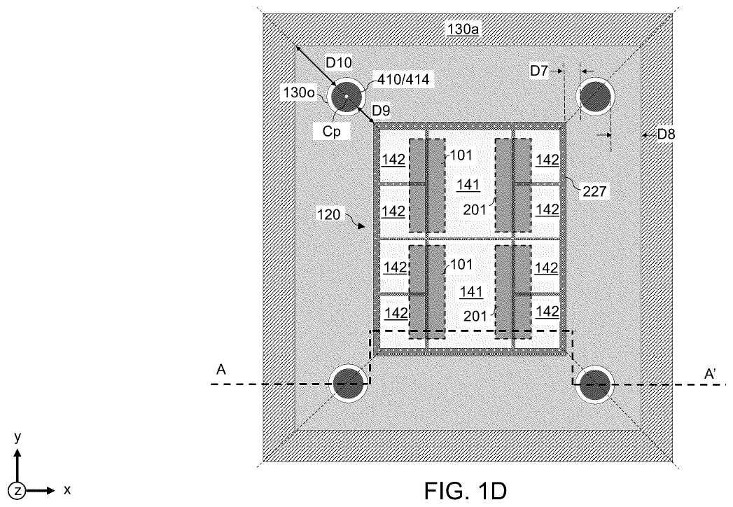

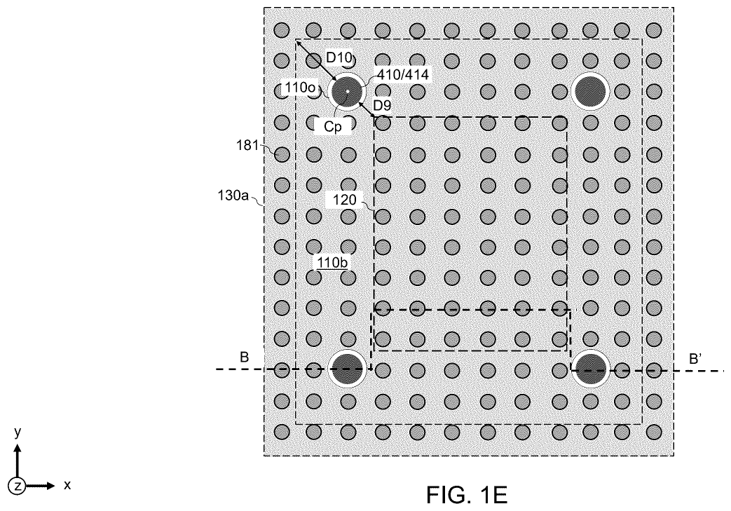

FIG. 1A is a vertical cross-sectional view of a package structure 100 according to one or more embodiments. FIG. 1B is a vertical cross-sectional view of a package module 120 in the package structure 100 according to one or more embodiments. FIG. 1C is a detailed vertical cross-sectional view of the package structure 100 according to one or more embodiments. FIG. 1D is a top-down view of the package structure 100 according to one or more embodiments. The vertical cross-sectional views in FIGS. 1A-1C are along the line A-A′ in FIG. 1D. FIG. 1E is a bottom-up view of the package structure 100 according to one or more embodiments. The vertical cross-sectional views in FIGS. 1A-1C are also along the line B-B′ in FIG. 1E.

As illustrated in FIG. 1A, the package structure 100 may include a package substrate 110, a package module 120 on the package substrate 110, and a package lid 130 including a package lid plate portion 130p over the package module 120 and a package lid foot portion 130a connected to the package lid plate portion 130p and attached to the package substrate 110. The package structure 100 may also include a fastening member 400 located at a corner of the package module 120 and configured to fasten the package lid plate portion 130p to the package substrate 110. The fastening member 400 may include, for example, a bolt 410 and a nut 420 threadedly attached to the bolt 410. Other types of fastening members 400 such as screws, rivets, pins, clips, clamps, snap-fit fasteners, anchors, studs, etc. are within the contemplated scope of disclosure.

The fastening member 400 may mitigate against semiconductor package warpage and therefore, mitigate against the package lid plate portion 130p from separating from the package module 120. By locating the fastening member 400 at the corner of the package module 120, the fastening member 400 may be especially effective at mitigating against the risk of separation at the corner of the package module 120 where the risk of separation may be the greatest. The fastening member 400 may, therefore, help to maintain a heat conduction path between the package module 120 and the package lid plate portion 130p. The bolt 410 may thereby mitigate against heat dissipation issues that may often arise in advanced packaging having a large size and high power and performance requirements.

As further illustrated in FIG. 1A, the package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials for use in forming the through vias 112a are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include a plurality of metal layers (e.g., copper traces) and a plurality of metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate 110 may also include a package substrate upper passivation layer 110a on the chip-side surface of the package substrate upper dielectric layer 114. The package substrate upper passivation layer 110a may partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include a plurality of metal layers (e.g., copper traces) and a plurality of metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate 110 may also include a package substrate lower passivation layer 110b on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) 180 including a plurality of solder balls 181 may be formed on the board-side surface of the package substrate lower dielectric layer 116. The BGA 180 including the solder balls 181 may allow the package structure 100 to be securely mounted on a substrate such as a printed circuit board (PCB) and electrically coupled to the substrate. The solder balls 181 may contact the package substrate lower bonding pads 116a, respectively. The solder balls 181 may therefore be electrically connected to the package substrate upper bonding pads 114a by way of the package substrate lower bonding pads 116a, metal interconnect structures 116b, the through vias 112a and the metal interconnect structures 114b.

The package module 120 may include one or more first semiconductor dies 141 and a plurality of second semiconductor dies 142 adjacent the first semiconductor dies 141 (see FIGS. 1A, 1B, 1D). The first semiconductor die 141 and second semiconductor dies 142 may be referred to collectively as the semiconductor dies 140. The semiconductor dies 140 may be electrically coupled to the BGA 180 through the package substrate 110. Although the package module 120 is illustrated as including a particular number of semiconductor dies having a particular arrangement, the number of semiconductor dies and the arrangement of the semiconductor dies is not limited to any particular number and arrangement. In particular, the package module 120 may include any number and arrangement of semiconductor dies. The package module 120 may also include the semiconductor dies mounted directly onto the package substrate 110 without any intervening interposers, redistribution layers, etc.

The package module 120 may be connected to the package substrate 110 by a plurality of C4 bumps 121 on the board-side surface of the package module 120. The C4 bumps 121 may be bonded to the package substrate upper bonding pads 114a in the package substrate 110. The C4 bumps 121 may be bonded to the package substrate upper bonding pads 114a by using, for example, solder reflow, compression bonding, thermo-compression bonding, etc. The C4 bumps 121 may include a metal pillar (e.g., copper pillar) and a solder bump (e.g., SnAg solder bump) on the metal pillar. In at least one embodiment, the solder bump may be collapsed to join the metal pillar of the C4 bump 121 to the package substrate upper bonding pads 114a.

A package underfill layer 119 may be formed on the package substrate 110 under and around the package module 120. The package underfill layer 119 may also be formed around the C4 bumps 121. The package underfill layer 119 may thereby securely fix the package module 120 to the package substrate 110. The package underfill layer 119 may be formed of an underfill material such as an epoxy-based polymeric material. Other suitable materials may be used for the package underfill layer 119.

In at least one embodiment, an outer molding material layer (not shown) may be formed on the package substrate 110 around the package module 120. The outer molding material layer may also be formed on and around the package underfill layer 119 that is under and around the package module 120. An upper surface of the outer molding material layer may be substantially coplanar with an upper surface of the package module 120. The outer molding material layer may include, for example, a polymeric material and in particular, an epoxy-based polymeric material (e.g., epoxy mold compound (EMC)). Other suitable material may be used in the outer molding material layer.

A TIM layer 170 may be located on the package module 120. The TIM layer 170 may include one or more layers. In at least one embodiment, a center of the TIM layer 170 may be substantially aligned with a center of the package module 120. The TIM layer 170 may have a low bulk thermal impedance and high thermal conductivity. The TIM layer 170 may cover an entire area of the upper surface of the package module 120. In at least one embodiment, the TIM layer 170 may have a thickness (e.g., a greatest thickness in the z-direction) in a range from 100 μm to 300 μm. The TIM layer 170 may be attached to the upper surface of the package module 120 by a thermally conductive adhesive (not shown).

The TIM layer 170 may include, for example, a graphite TIM layer including graphite or a metal TIM layer including one or more metals. The TIM layer 170 may include, for example, a low-melting-temperature (LMT) metal TIM or liquid metal TIM. The TIM layer 170 may include one or more metals such as indium, tin, gallium, silver, etc. The TIM layer 170 may include, for example, a gallium base, indium base, silver base, solder base, etc. The solder base may include tin and one or more other elements such as copper, silver, bismuth, indium, zinc, antimony, etc.

The TIM layer 170 may alternatively or additionally include a thermal grease, a thermal paste, thermal film, thermal adhesive, thermal gap filler, thermal pad (e.g., silicone), thermal tape or a gel-type TIM (e.g., a cross-linked polymer film). In at least one embodiment, the TIM layer 170 may include carbon nanotubes (CNTs), phase-change material (PCM), etc. The PCM may include, for example, a polymer based PCM. In at least one embodiment, the PCM may change its phase from solid to high-viscosity semi liquid around 60° C. Other materials in the TIM layer 170 are within the contemplated scope of this disclosure.

The TIM layer 170 may be formed on the package module 120 to promote the dissipation of heat generated during operation of the package structure 100 (e.g., operation of the semiconductor dies 140). The TIM layer 170 may have a low bulk thermal impedance and high thermal conductivity. The bond-line-thickness (BLT) (e.g., a distance between the package lid 130 and the package module 120) may be less than about 100 μm, although greater or lesser distances may be used. The BLT may also be substantially uniform over the entire area of the upper surface of the package module 120.

The package lid 130 may be mounted on the package substrate 110 over the package module 120 and contact the TIM layer 170. The package lid 130 may be formed of a metal such as copper with a nickel coating, or an aluminum alloy. The package lid 130 may alternatively be formed of a ceramic material or hard plastic (polymer) material. Other suitable package lid materials are within the contemplated scope of disclosure. The package lid 130 may help to provide rigidity to the package substrate 110.

The package lid foot portion 130a of the package lid 130 may be fixed to the package substrate 110 by an adhesive 160 such as a silicone adhesive or an epoxy adhesive. Other adhesives are within the contemplated scope of this disclosure. The package lid foot portion 130a may be attached to the package substrate 110 so as to surround (e.g., laterally surround; encircle) the package module 120 in the x-y plane. The package lid foot portion 130a may extend in a substantially perpendicular direction (e.g., in the z-direction) from the package substrate 110.

The package lid plate portion 130p may be integrally formed (e.g., formed as a unit) with the package lid foot portion 130a. The package lid plate portion 130p may alternatively be separately formed from the package lid foot portion 130a and attached to the package lid foot portion 130 by an adhesive. The package lid plate portion 130p may cover an entirety of the package module 120. The package lid plate portion 130p may contact at least a portion of the TIM layer 170. In at least one embodiment, the package lid plate portion 130p may directly contact an entire upper surface of the TIM layer 170. The package lid plate portion 130p may have a plate shape (e.g., planar shape) and be substantially parallel to an upper surface of the package substrate 110. The package lid plate portion 130p may extend, for example, in an x-y plane in FIG. 1A. The package lid plate portion 130p may include a central portion that is substantially aligned in the z-direction with a central portion of the package substrate 110.

As illustrated in FIG. 1A, the bolt 410 may include a bolt head 412. The bolt head 412 may contact the package substrate lower passivation layer 110b on the board-side surface of the package substrate lower dielectric layer 116. The bolt head 412 may provide a surface for applying torque during tightening or loosening. The bolt head 412 may include, for example, a hexagonal head, round head, square head, countersunk head, flange head, etc.

The bolt 410 may also include a shank 414. The shank 414 may be integrally formed with the bolt head 412. The shank 414 may have a substantially cylindrical shape. In particular, the shank 414 may have a circular cylindrical shape, square cylindrical shape, etc. Other shapes are within the contemplated scope of disclosure.

The shank 414 may include a first end adjoining the bolt head 412 and a second end having a threaded portion 414a. The shank 414 may also include an unthreaded portion between the bolt head 412 and the threaded portion 414a. The shank 414 may alternatively be fully threaded in which case the unthreaded portion may be absent. The threaded portion 414a of the shank 414 may include helical grooves cut or rolled into the cylindrical body of the shank 414. The threaded portion 414a may include a plurality of threads.

The shank 414 may extend from the package substrate 110 to the package lid plate portion 130p. The package substrate 110 may include an opening 110o and the package lid plate portion 130p may include an opening 130o. The opening 110o in the package substrate 110 may be substantially aligned in the z-direction with the opening 130o in the package lid plate portion 130p. The first end of the shank 414 may be inserted in the opening 110o of the package substrate 110. The second end of the shank 414 may be inserted in the opening 130o of the package lid plate portion 130p. The shank 414 may extend substantially in the z-direction and perpendicular to an upper surface of the package substrate 110.

The threaded portion 414a of the shank 414 may extend out of the opening 130o in the package lid plate portion 130p. The nut 420 of the fastening member 400 may have a substantially annular shape and have a threaded inner wall. The nut 420 may be threadedly attached to the threaded portion 414a of the shank 414 so that the threads of the nut 420 engage the threads of the threaded portion 414a of the shank 414. The nut 420 may contact an upper surface of the package lid plate portion 130p. The nut 420 may have a hexagonal shape, round shape, square shape, etc.

The bolt 410 and nut 420 may be made from the same or different materials. The fastening member 400 including the bolt 410 and nut 420 may be made from one or more materials that ensure high thermal and electrical performance, corrosion resistance, and mechanical stability. In particular, the fastening member 400 may include stainless steel, copper alloys, aluminum alloys, tungsten, molybdenum, etc. The fastening member 400 may also include a coating (e.g., protective coating) such as a nickel, ceramic coating, etc. Other suitable materials for the fastening member 400 are within the contemplated scope of disclosure.

With this configuration, the bolt head 412 may connect the first end of the shank 414 to the package substrate 110 and the nut 420 may connect the second end of the shank 414 to the package lid plate portion 130p. In particular, the nut 420 may apply a downward force on the package lid plate portion 130p and the bolt head 412 may apply an upward force on the package substrate 110. The nut 420 and bolt head 412 may, therefore, serve to force together the package lid plate portion 130p and the package substrate 110. As a result, an extent of package warpage may be reduced and a likelihood of the package lid plate portion 130p becoming separated from the package module 120 may also be reduced. In other embodiments, the bolt 400 may be inserted through opening 130o of the package lid plate portion 130p and engage a nut 420 that is located below the package substrate 110.

Referring again to FIG. 1B, the package module 120 may include a lower RDL structure 120A and a lower molded portion 120B on the lower RDL structure 120A. The package module 120 may also include an upper RDL structure 120C on the lower molded portion 120B and an upper molded portion 120D on the upper RDL structure 120C.

In at least one embodiment, the lower RDL structure 120A may include a plurality of polymer layers 12 and a plurality of redistribution layers 12a stacked alternately. The number of the polymer layers 12 and/or the number of redistribution layers 12a in the lower RDL structure 120A are not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof. Other suitable conductive materials may be within the contemplated scope of disclosure.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm, although lesser or greater thicknesses may also be used. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12, and may extend in the x-direction (first horizontal direction) and y-direction (second horizontal direction) on an upper surface of the polymer layers 12. The C4 bumps 121 may be formed on a board-side surface of the lower RDL structure 120A. The C4 bumps 121 may be electrically coupled to the redistribution layers 12a.

The lower molded portion 120B may be formed on the lower RDL structure 120A. The lower molded portion 120B may have a length in the x-direction that is substantially the same as a length in the x-direction of the lower RDL structure 120A. The lower molded portion 120B may have a width in the y-direction that is substantially the same as a width in the y-direction of the lower RDL structure 120A. The lower molded portion 120B may have a thickness in the z-direction greater than a thickness of the lower RDL structure 120A.

The lower molded portion 120B may include a lower molding material layer 127 (e.g., encapsulation layer) formed on the lower RDL structure 120A. In at least one embodiment, the lower molding material layer 127 may be formed of a curable material that may cure to form a hard, solid structure. The lower molding material layer 127 may include, for example, epoxy molding compound (EMC). In at least one embodiment, the lower molding material layer 127 may include a polymeric material and in particular, an epoxy-based polymeric material. Other suitable molding materials may be used.

In at least one embodiment, the lower molding material layer 127 may have a coefficient of thermal expansion (CTE) that is substantially similar to a CTE of the lower RDL structure 120A. In at least one embodiment, the lower molding material layer 127 may include an added material (e.g., filler material) for improving a property of the lower molding material layer 127 (e.g., thermal conductivity, CTE, etc.). The added material may include, for example, metal powder, metal oxide powder, etc. Other materials in the lower molding material layer 127 are within the contemplated scope of the disclosure.

The lower molded portion 120B of the package module 120 may also include one or more interconnect dies 10. The interconnect dies 10 may include one or more local silicon interconnect (LSI) dies 101 and one or more local redistribution interconnect (LRI) dies 201. The interconnect dies 10 may be surrounded (e.g., at least in the x-direction and y-direction) by the lower molding material layer 127. In at least one embodiment, the lower molding material layer 127 may contact a substantial entirety of the sidewalls of the interconnect dies 10 (e.g., the interconnect dies 10 may be substantially embedded in the lower molding material layer 127. The interconnect dies 10 may interconnect the semiconductor dies 140. The interconnect dies 10 may be passive interconnect dies or active interconnect dies 10.

In at least one embodiment, the interconnect dies 10 may include an LSI die 101 that interconnects (e.g., electrically couples) the first semiconductor die 141 to one or more second semiconductor dies 142. The LSI die 101 may include a bulk semiconductor portion 101a (e.g., bulk silicon portion) on the lower RDL structure 120A. The LSI die 101 may also include an interconnect portion 101b including metal interconnects 101b1 on the bulk semiconductor portion 101a. The LSI die 101 may also include one or more LSI bonding pads 104 on an upper surface of the LSI die 101. The LSI bonding pads 104 may be electrically coupled to the metal interconnects 101b1 in the interconnect portion 101b. The LSI die 101 may also include one or more through vias 106 (e.g., through silicon vias (TSVs)) in the bulk semiconductor portion 101a. The through vias 106 may electrically couple the metal interconnects 101b1 in the interconnect portion 101b to the redistribution layers 12a in the lower RDL structure 120A. Each of the metal interconnects 101b1, LSI bonding pads 104, and through vias 106 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

In at least one embodiment, the interconnect dies 10 may include an LRI die 201 that interconnects (e.g., electrically couples) the first semiconductor die 141 to one or more second semiconductor dies 142 on an opposite side of the first semiconductor die 141. The LRI die 201 may include a bulk semiconductor portion 201a (e.g., bulk silicon portion) on the lower RDL structure 120A. The LRI die 201 may also include a redistribution portion 201c including metal redistribution layers 201c1 on the bulk semiconductor portion 201a. The LRI die 201 may also include one or more LRI bonding pads 204 on an upper surface of the LRI die 201. The LRI bonding pads 204 may be electrically coupled to the metal redistribution layers 201c1 in the redistribution portion 201c. The LRI die 201 may also include one or more through vias 206 (e.g., TSVs) in the bulk semiconductor portion 201a. The through vias 106 may electrically couple the metal redistribution layers 201c1 in the redistribution portion 201c to the redistribution layers 12a in the lower RDL structure 120A. Each of the metal redistribution layers 201b1, LRI bonding pads 204, and through vias 206 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The lower molded portion 120B of the package module 120 may also include one or more through insulator vias (TIVs) 123 in the lower molding material layer 127. The TIVs 123 may be located adjacent the interconnect dies 10 and may have a thickness substantially equal to a thickness of the lower molding material layer 127. The TIVs 123 may be connected to the redistribution layers 12a of the lower RDL structure 120A. The TIVs 123 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The lower molded portion 120B may also integrate additional elements, such as stand-alone integrated passive devices (IPDs) (not shown). In at least one embodiment, the IPDs may be located in the lower molding material layer 127 underneath one or more of the first semiconductor dies 141 and second semiconductor dies 142 (see FIG. 1D) to support signal communication.

As further illustrated in FIG. 1B, the upper RDL structure 120C of the package module 120 may have a structure substantially similar to that of the lower RDL structure 120A. In particular, the upper RDL structure 120C may include a plurality of polymer layers 13 and a plurality of redistribution layers 13a stacked alternately. The number of the polymer layers 13 and/or the number of redistribution layers 13a in the upper RDL structure 120C are not limited by the disclosure. The materials that may be used in the polymer layers 13 may be substantially the same as the materials that may be used in the polymer layers 12. The materials that may be used in the redistribution layers 13a may bs substantially the same as the materials that may be used in the redistribution layers 12a. The structure (e.g., thickness) of the redistribution layers 13a may be substantially the same as the structure of the redistribution layers 12a.

The redistribution layers 13a in the upper RDL structure 120C may contact the TIVs 123 in the lower molded portion 120B. The redistribution layers 13a may be electrically coupled to the redistribution layers 12a in the lower RDL structure 120A by the TIVs 123. The redistribution layers 13a may also contact the LSI bonding pads 104 in the LSI die 101 and the LRI bonding pads in the LRI die 201.

The upper RDL structure 120C may also include a plurality of bonding pads 214 on an upper surface of the upper RDL structure 120C. The bonding pads 214 may be substantially similar to the LSI bonding pads 104 and LRI bonding pads 204. In particular, the materials that may be used in the bonding pads 214 may be substantially the same as the materials that may be used in the LSI bonding pads 104 and LRI bonding pads 204.

The upper molded portion 120D of the package module 120 may be formed on the upper RDL structure 120C. The upper molded portion 120D may include the semiconductor dies 140. The semiconductor dies 140 may be connected to the bonding pads 214 on the upper surface of the upper RDL structure 120C by a plurality of die connection structures such as microbumps 219. The microbumps 219 may each include a copper post and a solder bump on the copper post. The microbumps 219 may be bonded by the solder bump to bonding pads 214. The microbumps 219 may be electrically coupled to the TIVs 123, LSI die 101 and LRI die 201 by the upper RDL structure 120C.

The package module 120 may also include a package module underfill layer 129 that is formed (e.g., individually or collectively) under and around each of the semiconductor dies 140. The package module underfill layer 129 may also be formed around the microbumps 219. The package module underfill layer 129 may thereby fix each of the semiconductor dies 140 to the upper RDL structure 120C. The package module underfill layer 129 may be formed of an epoxy-based polymeric material. Other suitable materials may be used for the package module underfill layer 129.

Each of the semiconductor dies 140 may include, for example, a singular semiconductor die, a system-on-chip die or a system-on-integrated chips die, and may be implemented by chip-on-wafer-on-substrate technology or integrated fan-out-on-substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, an inverted AND (NAND) die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., system-on-chip die), and the second semiconductor die 142 may include an ancillary die (e.g., memory/system-on-chip die, HBM die, etc.).

The upper molded portion 120D of the package module 120 may also include an upper molding material layer 227 formed around the semiconductor dies 140. The upper molding material layer 227 may also be formed on and around the package module underfill layer 129. The upper molding material layer 227 may have an outer sidewall that is substantially aligned with an outer sidewall of the polymer layers 13 in the upper RDL structure 120C, an outer sidewall of the lower molding material layer 127 and an outer sidewall of the polymer layers 12 in the lower RDL structure 120A.

In at least one embodiment, the upper molding material layer 227 may be formed on sidewalls (inner sidewall and outer sidewall) of each of the semiconductor dies 140. In at least one embodiment, an upper surface of the package module underfill layer 129 may be recessed from upper surface of the semiconductor dies 140a. In that case, the upper molding material layer 227 may be formed on the upper surface of the package module underfill layer 129 between the semiconductor dies 140. The upper molding material layer 227 may be formed between and bonded to the sidewalls of each of the semiconductor dies 140. The upper molding material layer 227 may also be bonded to the chip-side surface of the upper RDL structure 120C and the package module underfill layer 129.

As illustrated in FIG. 1B, the upper molding material layer 227 may include an upper surface that is substantially coplanar with the upper surface 140a of the semiconductor dies 140. The upper surface of the upper molding material layer 227 may alternatively or additionally include a recessed upper surface (not shown) that is recessed in the z-direction from the upper surface 140a of the semiconductor dies 140. In at least one embodiment, the recessed upper surface may constitute an entirety of an upper surface of the upper molding material layer 227.

In at least one embodiment, the upper molding material layer 227 may be formed of a curable material that may cure to form a hard, solid structure. The upper molding material layer 227 may include, for example, epoxy molding compound (EMC). In at least one embodiment, the upper molding material layer 227 may include a material that is substantially similar to the package module underfill layer 129, and or substantially similar to the lower molding material layer 127 in the lower molded portion 120B. In at least one embodiment, the upper molding material layer 227 may include a polymeric material and in particular, an epoxy-based polymeric material. Other suitable molding materials may be within the contemplated scope of disclosure.

In at least one embodiment, the upper molding material layer 227 may have a CTE that is substantially similar to a CTE of the upper RDL structure 120C, a CTE of the lower molded portion 120B and/or a CTE of the lower RDL structure 120A. In at least one embodiment, the upper molding material layer 227 may include an added material (e.g., filler material) for improving a property of the upper molding material layer 227 (e.g., thermal conductivity, CTE, etc.). The added material may include, for example, metal powder, metal oxide powder, etc. Other materials in the upper molding material layer 227 are within the contemplated scope of the disclosure.

Referring again to FIG. 1C, the bolt 410 including the bolt head 412 and shank 414 may have a length L410 in the z-direction (e.g., vertical direction). The length L410 of the bolt 410 may be greater than a distance between an upper surface of the package lid plate portion 130p and a lower surface of the package substrate lower passivation layer 110b. The nut 420 may have a thickness T1 in a range from 2 mm to 6 mm, although thicker or thinner nut 420 thickness may be used. The bolt head 412 may have a thickness T2 also in a range from 2 mm to 6 mm, although thicker or thinner bolt head 412 thickness may be used. A thickness T3 of the package lid plate portion 130p may be in a range, for example, of 1 mm to 5 mm (e.g., 2 mm to 3 mm), although thicker or thinner package lid plate portion 130p thickness may be used. A thickness T4 of the package substrate 110 is not necessarily limited but may be in a range, for example, of 1 mm to 8 mm.

The nut 420 may have a width D1 in the x-direction in a range from 6 mm to 10 mm, although wider or narrower widths may be used. The shank 414 may have a width D2 in the x-direction in a range from 3 mm to 8 mm, although wider or narrower widths may be used. The bolt head 412 may have a width D3 in the x-direction also in a range from 6 mm to 10 mm, although wider or narrower widths may be used. The bolt head 412 may be separated from an adjacent solder ball 181 of the BGA 180 by a distance D4 that is greater than 1 cm.

The opening 130o in the package lid plate portion 130p may have a width D5 in a range from 4 mm to 9 mm. The opening 110o in the package substrate 110 may have a width D6 also in a range from 4 mm to 9 mm. In at least one embodiment, the width D5 may be substantially the same as the width D6. Each of the width D5 and the width D6 may be in a range from 5% to 20% greater than the width D2 of the shank 414. In at least one embodiment, the width D5 and/or the width D6 may be no more than 5% greater than the width D2 of the shank 414 to ensure that the shank 414 fits tightly in the opening 110o and opening 130o.

Further, the width D1 of the nut 410 may be at least 30% greater than the width D5 of the opening 130o in the package lid plate portion 130p. The width D2 of the bolt head 412 may be at least 30% greater than the width D6 of the opening 110o in the package substrate 110.

The shank 414 of the bolt 410 may be separated from a sidewall of the package module 120 by a lateral distance D7 in a range from 1 cm to 2 cm. A distance D8 between the shank 414 and the package lid foot portion 130a is not necessarily limited but may be, for example, in a range from 1.5 cm to 6 cm. The distance D8 may be greater than the lateral distance D7. In at least one embodiment, the distance D8 may be at least 20% greater than the lateral distance D7. It should be noted that other widths, thicknesses and dimensions are within the contemplated scope of disclosure.

Referring again to FIG. 1D, the package lid plate portion 130p, TIM layer 170 and nut 420 are omitted from FIG. 1D for ease of explanation. A location of the LSI die 101 and LRI die 201 beneath the semiconductor dies 140 are shown as shadows in FIG. 1D.

As illustrated in FIG. 1D, the second semiconductor dies 142 may be substantially aligned in columns extending in the y-direction on opposing sides of the first semiconductor die 141. The second semiconductor dies 142 may also be substantially aligned in rows extending in the x-direction on the opposing sides of the first semiconductor dies 141. The upper molding material layer 227 in the package module 120 may be formed around all of the semiconductor dies 140.

As further illustrated in FIG. 1D, the LSI die 101 may extend lengthwise in the y-direction. The LSI die 101 may be located under the first semiconductor die 141 and one or more of the second semiconductor dies 142 on a side of the first semiconductor die 141. The LRI die 201 may be located under the first semiconductor die 141 and one or more of the second semiconductor dies 142 on an opposite side of the first semiconductor die 141.

The package structure 100 may have a substantially rectangular shape extending lengthwise in the y-direction. The first semiconductor die 141 may also have a substantially rectangular shape extending lengthwise in the y-direction. Other suitable shapes are within the contemplated scope of disclosure.

The package module 120 may also have a substantially rectangular shape extending lengthwise in the y-direction. An outer shape of the package module 120 may be substantially defined by an outer shape of the upper molding material layer 227. The upper molding material layer 227 may have a width W1 that is substantially uniform around an entirety of the upper molding material layer 227.

As further illustrated in FIG. 1D, the package module 120 may include a plurality of corners (e.g., four corners) and the package structure 100 may include a plurality of bolts 410 located at the plurality of corners of the package module 120 respectively. Further, the opening 130o may be located in the package lid plate portion 130p so that the shank 414 in the opening 130o may be located at (e.g., near) a corner of the package module 120. The phrase “at the corner of the package module 120” may be understood to mean separated from the corner of the package module 120 by a lateral distance no greater than 2 cm.

In particular, the opening 130o may be located in the package lid plate portion 130p such that the shank 414 of the bolt 410 may be located on a diagonal line from a corner of the package module 120 to an inner corner of the package lid foot portion 130a. The shank 414 may be separated from the corner of the package module 120 in a diagonal direction (e.g., on the diagonal line) by a distance D9 in a range from 1 cm to 2 cm. The opening 130o may also be located in the package lid plate portion 130p such that shank 414 may be separated from the inside corner of the package lid foot portion 130a in a diagonal direction by a distance D10 in a range from 1 cm to 2 cm. In at least one embodiment, the distance D10 may be greater than the distance D9. In at least one embodiment, the distance D10 may be at least 50% greater than the distance D9. In at least one embodiment, the distance D10 may be in a range from 1.5 cm to 6 cm.

Further, the opening 130o may be located in the package lid plate portion 130p so that the shank 414 of the bolt 410 may be substantially located on the diagonal line and aligned with the inside corner of the package lid foot portion 130a and the corner of the package module 120. In at least one embodiment, a centerpoint Cp of the shank 414 may be located on the diagonal line and substantially aligned with the inside corner of the package lid foot portion 130a and the corner of the package module 120. In at least one embodiment, a greatest distance between the centerpoint Cp of the shank 414 and the diagonal line connecting the inside corner of the package lid foot portion 130a and the corner of the package module 120 may be no more than 50% of the radius of the cross-section of the shank 414.

Referring again to FIG. 1E, the bolt head 412 is omitted from the drawing ease of understanding. Further, a location of the package lid foot portion 130a and a location of the package module 120 are shown by dashed lines in the bottom-up view of FIG. 1E.

The opening 110o may be located in the package substrate 110 so that the shank 414 in the opening 110o may be located at the corner of the package module 120.

In particular, the opening 110o may be located in the package substrate 110 such that the shank 414 may be separated from the corner of the package module 120 in a diagonal direction by the distance D9 and such that shank 414 may be separated from the inside corner of the package lid foot portion 130a in a diagonal direction by the distance D10.

Further, the opening 110o may be located in the package substrate 110 so that the shank 414 of the bolt 410 may be substantially aligned with the inside corner of the package lid foot portion 130a and the corner of the package module 120. The opening 110o may also be located so as to ensure that a distance between the bolt head 412 (not shown) and an adjacent solder ball 181 is greater than 1 cm.

The solder balls 181 of the BGA 180 may be arranged in a two-dimensional array on the package substrate lower passivation layer 110b. Each of the bolts 410 may replace one of the solder balls 181 in the array of solder balls 181. Each of the bolts 410 may be substantially aligned with a row and a column of solder balls 181 of the BGA 180.

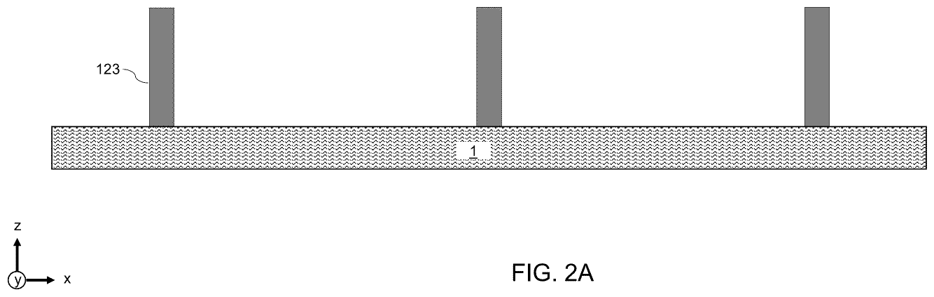

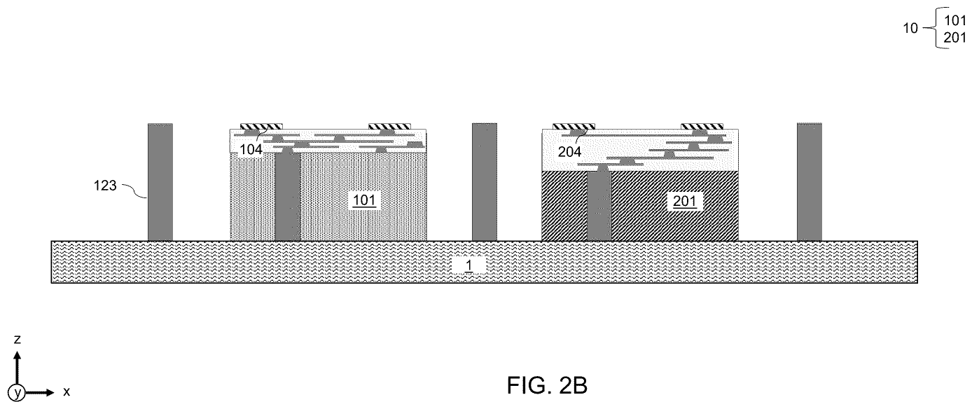

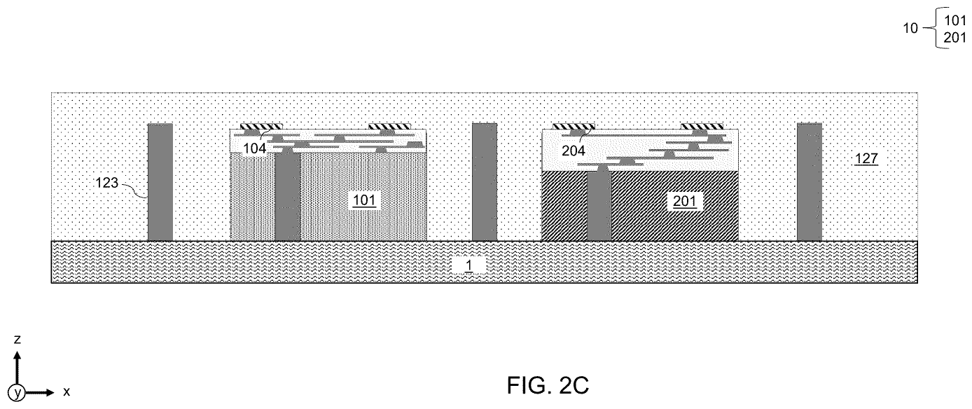

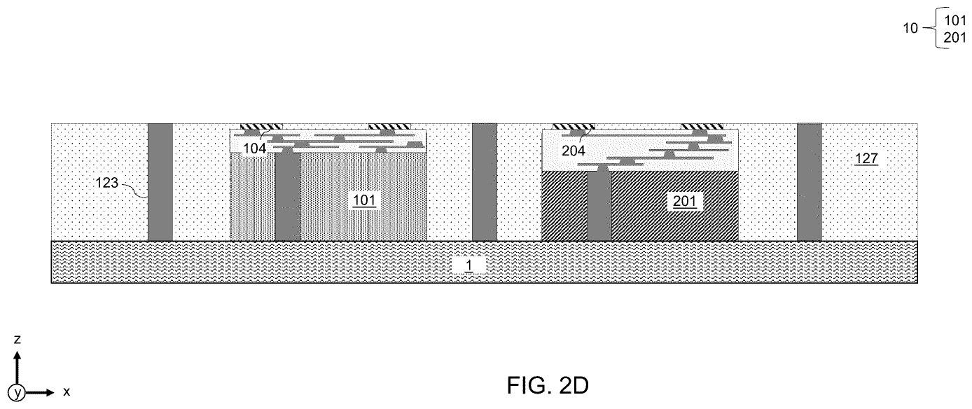

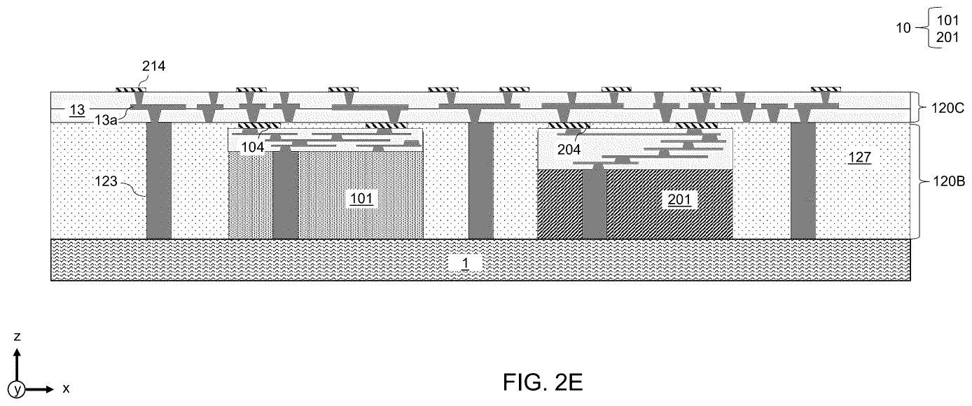

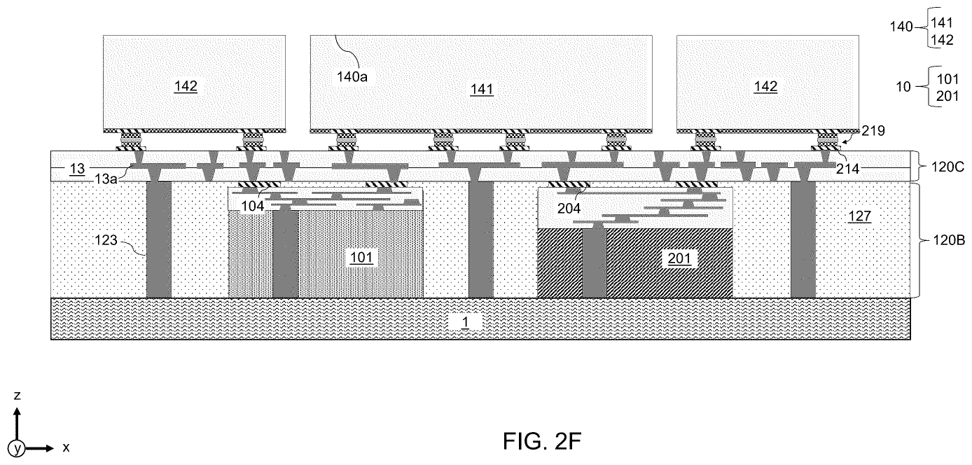

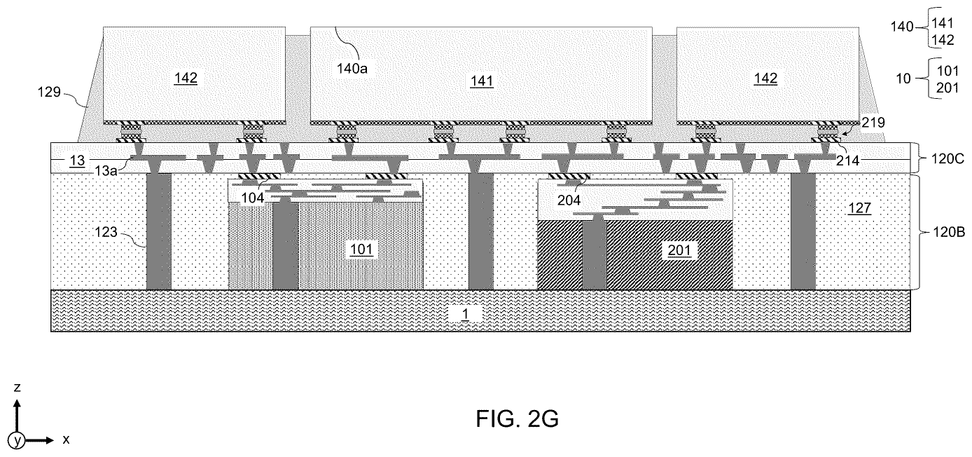

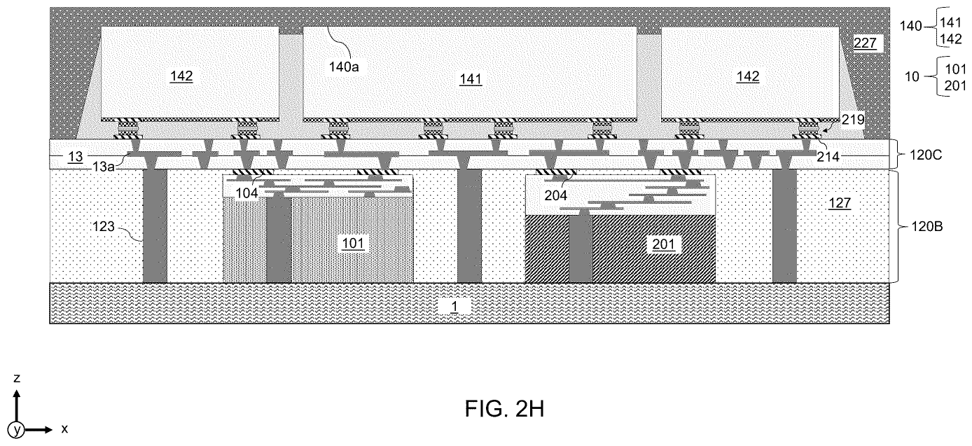

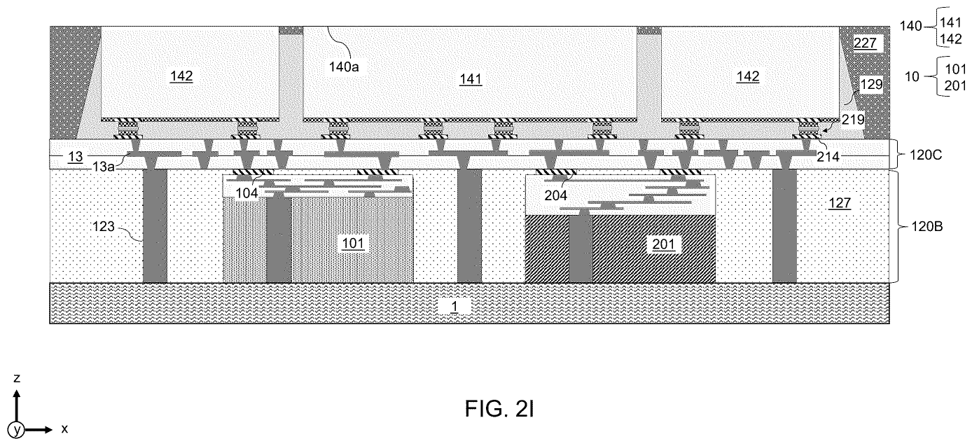

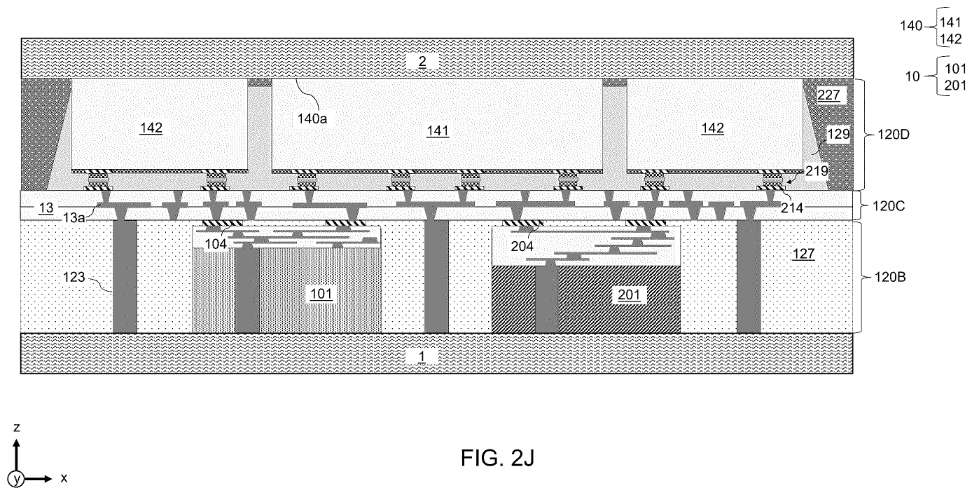

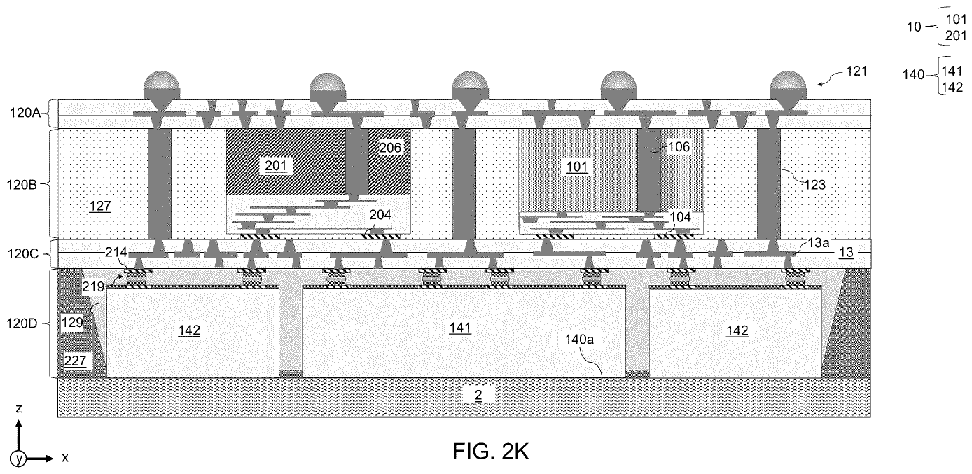

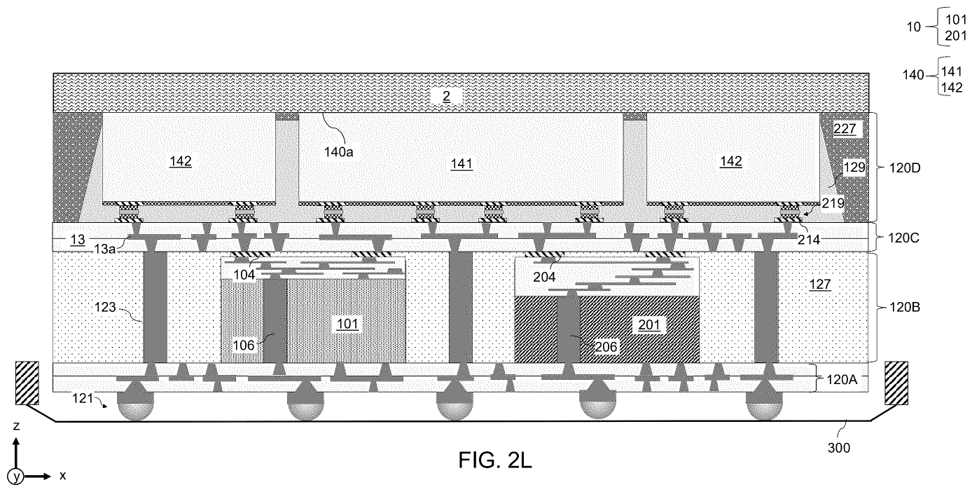

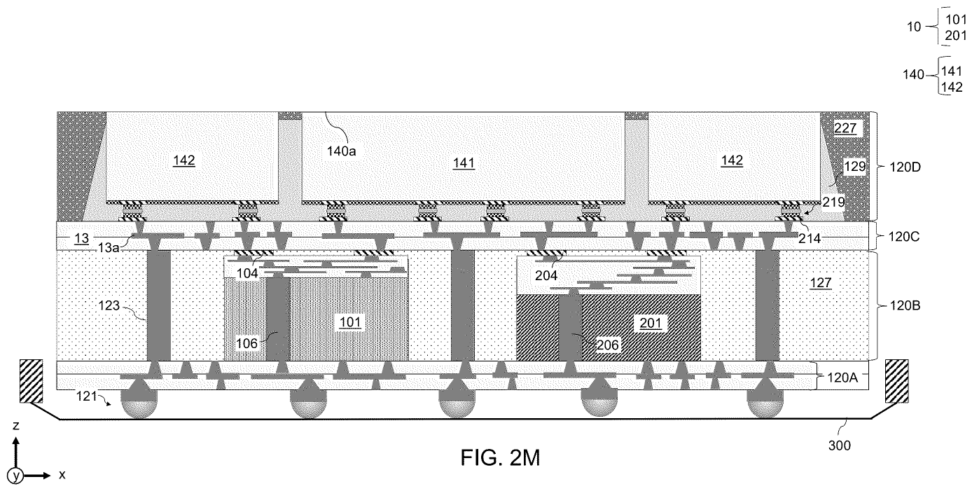

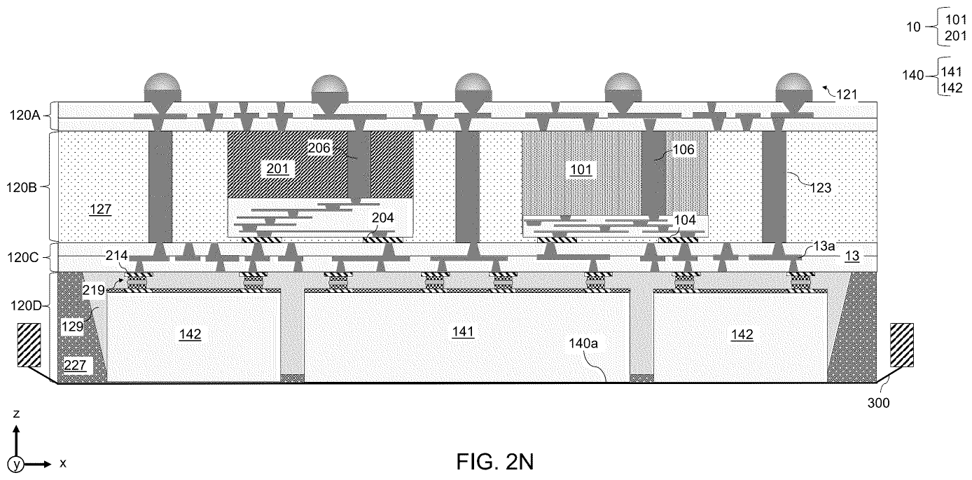

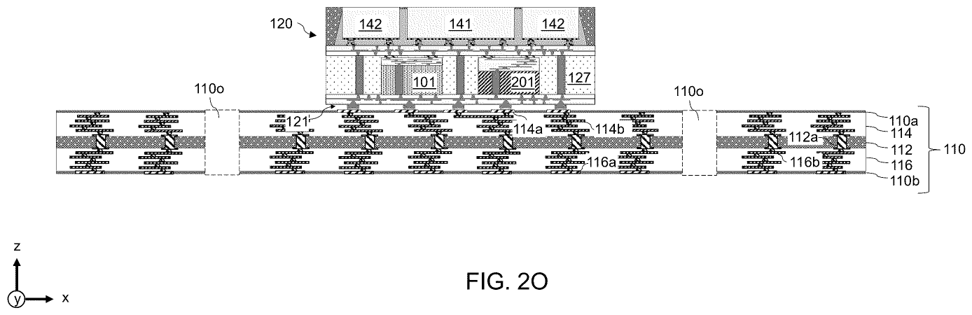

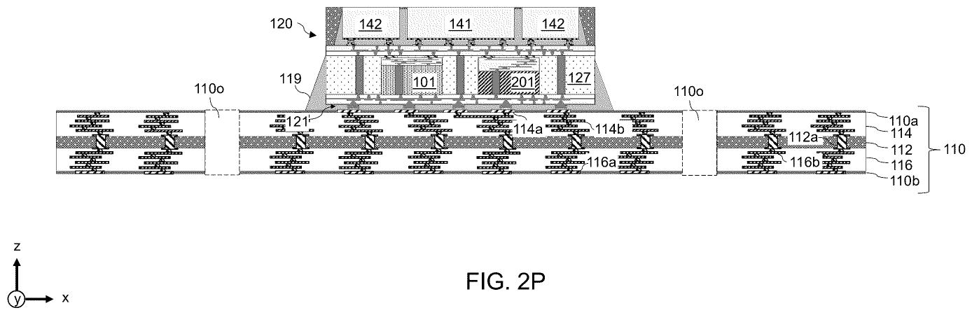

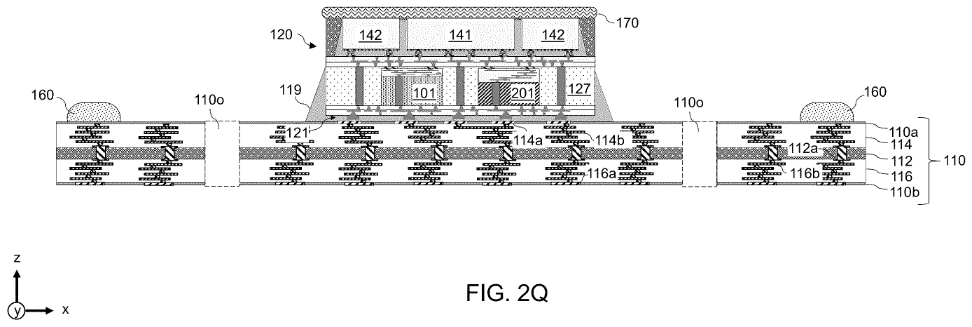

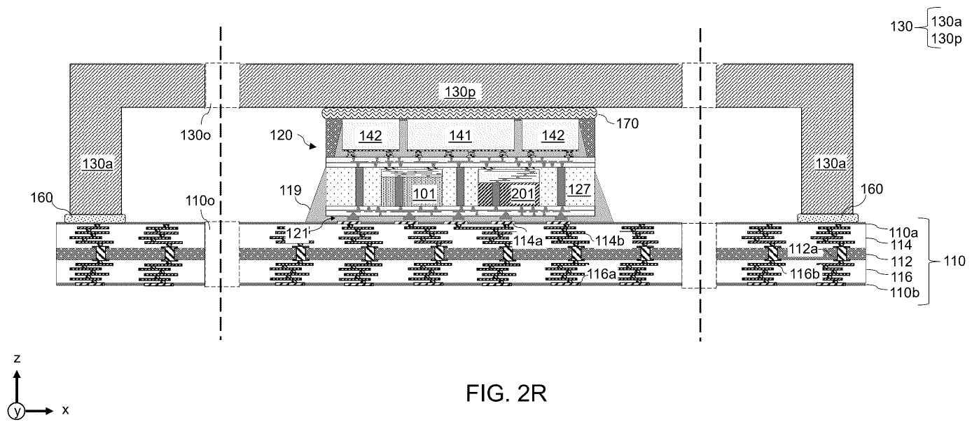

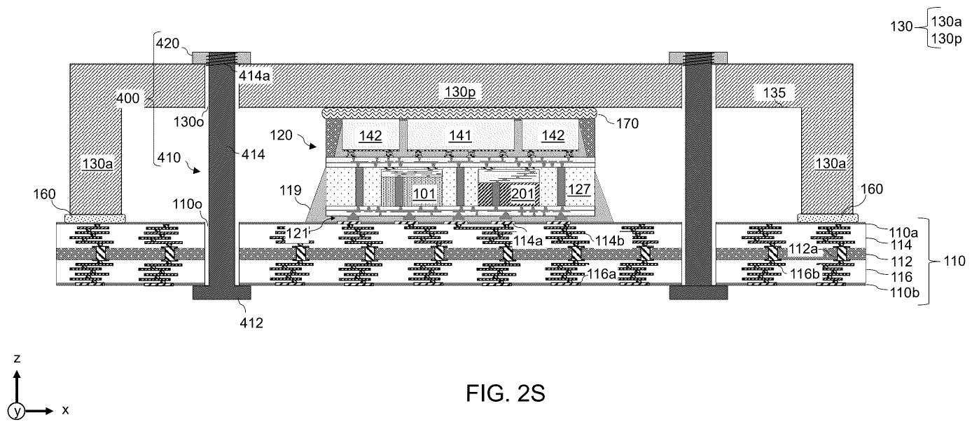

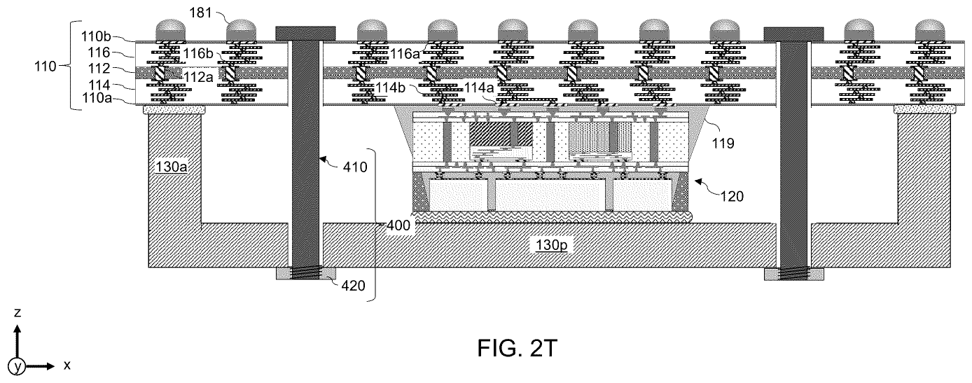

FIGS. 2A-2S illustrate various intermediate structures in a method of forming the package structure 100 according to one or more embodiments. FIG. 2A is a vertical cross-sectional view of an intermediate structure including the TIVs 123 on a first carrier substrate 1 (e.g., carrier wafer) according to an embodiment of the present invention.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used. In at least one embodiment, the carrier substrate 1 may include sapphire or glass and have a thickness of about 1000 μm.

An adhesive layer (e.g., die attach film (DAF); not shown) may be applied to the top surface of the first carrier substrate 1. The adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. For example, the LTHC layer may include Light-To-Heat Conversion Release Coating (LTHC) ink™ that may be commercially available. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

The TIVs 123 may formed in one or more electroplating processes. In one or more embodiments, a seed layer (not shown) may be formed on the carrier substrate 1. A metal material may then be electroplated on the seed layer to form the TIVs 123. In at least one embodiment, the TIVs 123 may be formed to have a thickness in a range from about 120 μm to 160 μm (e.g., about 140 μm). The metal material for electroplating may include, for example, one or more layers and may include metals, metal alloys, and/or other metal-containing compounds (e.g., Cu, Al, Mo, Co, Ru, W, TiN, TaN, WN, etc.). Other suitable metal materials as well as other suitable formations processes are within the contemplated scope of disclosure.

FIG. 2B is a vertical cross-sectional view of an intermediate structure including the interconnect dies 10 on the first carrier substrate 1 according to an embodiment of the present invention. The LSI die 101 and LRI die 201 may be placed on the first carrier substrate 1. In at least one embodiment, the LSI die 101 and LRI die 201 may be placed on the first carrier substrate 1 using an electromechanical pick-and-place (PNP) machine. As illustrated in FIG. 2B, a height of the LSI bonding pads 104 and LRI bonding pads 204 may be substantially the same as a height of the TIVs 123. The LSI die 101 and LRI die 201 may adhere to the first carrier substrate 1 by the adhesive layer (e.g., DAF; not shown).

FIG. 2C is a vertical cross-sectional view of an intermediate structure including the lower molding material layer 127 according to one or more embodiments. After the LSI die 101 and LRI die 201 are placed on the first carrier substrate 1, the lower molding material layer 127 (e.g., encapsulant layer) may be formed by a specialized molding process (e.g., A3+ molding process). The molding process may include, for example, preparing the molding compound (e.g., e.g., by mixing resin, hardener, fillers, and additives) and injecting (or depositing by spray coating, spin coating or other suitable method) the molding compound into a mold cavity around the LSI die 101 and LRI die 201. The molding compound may include an epoxy polymer material (e.g., an epoxy molding compound (EMC)). In at least one embodiment, the molding compound may be formed on the first carrier substrate 1 and fill in the gaps between the LSI die 101, LRI die 201 and the TIVs 123. The molding compound may encapsulate (e.g., in the x-direction, y-direction and z-direction) the LSI die 101, LRI die 201 and the TIVs 123. The molding process may further include curing the mold compound to achieve desired mechanical and thermal properties, and post-mold processing such as trimming, testing, etc.

As illustrated in FIG. 2C, the lower molding material layer 127 may be formed to have a thickness greater than a height of the TIVs 123 and a height of the LSI bonding pads 104 and the LRI bonding pads 204. In at least one embodiment, the lower molding material layer 127 may be formed to have a thickness in a range from about 170 μm to 210 μm (e.g., about 190 μm).

FIG. 2D is a vertical cross-sectional view of an intermediate structure after polishing (e.g., planarizing) the lower molding material layer 127 according to one or more embodiments. After the lower molding material layer 127 has cured, a planarization process may then be used to make an upper surface of the lower molding material layer 127 substantially coplanar with an upper surface of the LSI die 101, an upper surface of the LRI die 201 and an upper surface of the TIVs 123. In particular, the planarization process may be performed on the upper surface of the lower molding material layer 127 to expose the upper surface of the LSI bonding pads 104, the upper surface of the LRI bonding pads 204 and the upper surface of the TIVs 123. In at least one embodiment, the planarization process may be performed until a thickness of the lower molded portion 120B is in a range from 110 μm to 150 μm (e.g., about 129 μm). The planarization process may include, for example, a mechanical grinding process and/or a chemical mechanical polishing (CMP) process. This may complete the formation of the lower molded portion 120B of the package module 120.

FIG. 2E is a vertical cross-sectional view of an intermediate structure including the upper RDL structure 120C according to one or more embodiments. The upper RDL structure 120C may be formed by alternately forming the plurality of dielectric layers 13 and plurality of redistribution layers 13a on the lower molded portion 120B. Each dielectric layer 13 may be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 13 may then be patterned by a photolithographic process to form via holes in the dielectric layer 13. The photolithographic process may include forming a patterned photoresist mask (e.g., BL301; not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 13a (e.g., metal traces and metal vias) may be formed on the dielectric layer 13. The redistribution layer 13a may be formed, for example, by depositing (e.g., by CVD, PVD or other suitable deposition technique) one or more layers of metal material such as copper, aluminum, nickel, titanium, a combination thereof or other suitable metals, on the dielectric layer 13 and in the vias holes formed by patterning the dielectric layer 13. The redistribution layer 13a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 2E, the bonding pads 214 may be formed on the uppermost dielectric layer 13. The bonding pads 214 may include a metallic material that may be bonded to a solder material. The bonding pads 214 may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process to form the bonding pads 214. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

FIG. 2F is a vertical cross-sectional view of an intermediate structure including the semiconductor dies 140 on the upper RDL structure 120C according to one or more embodiments. The semiconductor dies 140 may be mounted concurrently on the upper RDL structure 120C in one process or mounted separately in separate processes.

The semiconductor dies 140 (including microbump portions) may be positioned over the upper RDL structure 120C using an electromechanical PNP machine. Each of the semiconductor dies 140 may be bonded to the upper RDL structure 120C by one or more of the microbumps 219. In at least one embodiment, the microbumps 219 may include a two-dimensional array of microbumps 219, and each of the semiconductor dies 140 may be attached to the bonding pads 214 by C2 bonding, (e.g., solder bonding). A C2 bonding process that reflows the solder portions of the microbumps 219 may be performed after the microbumps 219 on the semiconductor dies 140 are disposed over corresponding bonding pads 214 on the upper surface of the upper RDL structure 120C.

FIG. 2G is a vertical cross-sectional view of an intermediate structure including the package module underfill layer 129 according to one or more embodiments. The package module underfill layer 129 may be applied by depositing and/or injecting an epoxy-based polymeric material (e.g., U19T) onto the upper RDL structure 120C. The epoxy-based polymeric material may be applied on the lower molded portion 120B so as to be formed under the semiconductor dies 140 and around the microbumps 219. In at least one embodiment, the epoxy-based polymeric material may fill substantially all of the gaps between the semiconductor dies 140 and the lower molded portion 120B. The package module underfill layer 129 may then be cured, for example, in a box oven for about 90 minutes at about 150° C. to provide the package module underfill layer 129 with a sufficient stiffness and mechanical strength.

FIG. 2H is a vertical cross-sectional view of an intermediate structure including the upper molding material layer 227 according to one or more embodiments. The upper molding material layer 227 may be formed by dispensing a liquid molding material (e.g., EMC, epoxy molding material, A7 molding compound, etc.) onto the intermediate structure of FIG. 2G by a suitable dispensing tool. The upper molding material layer 227 may be dispensed onto the intermediate structure to have a height greater than the height of the upper surface 140a of the semiconductor dies 140. The semiconductor dies 140 may have a thickness, for example, in a range of about 400 μm to 1000 μm (e.g., about 692 μm).

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the upper RDL structure 120C, sizes of the semiconductor dies 140, etc.

In at least one embodiment, the molding material of the upper molding material layer 227 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around the semiconductor dies 140. The low viscosity may also help to avoid the formation of voids in the upper molding material layer 227. In at least one embodiment, the upper molding material layer 227 may be substantially free of voids.

FIG. 2I is a vertical cross-sectional view of an intermediate structure after polishing (e.g., planarizing) the upper molding material layer 227 according to one or more embodiments. After the upper molding material layer 227 has been adequately cured, the upper molding material layer 227 may be planarized so as to make the upper surface of the upper molding material layer 227 to be substantially coplanar with the semiconductor die upper surface 140a. The upper molding material layer 227 may be planarized, for example, by grinding, chemical mechanical polishing (CMP) or other suitable planarization technique. This may complete formation of the upper molded portion 120D of the package module 120.

FIG. 2J is a vertical cross-sectional view of an intermediate structure including a second carrier substrate 2 on the upper molded portion 120D according to one or more embodiments. The second carrier substrate 2 may be substantially the same as the first carrier substrate 1 (e.g., having a thickness of about 550 μm). The second carrier substrate 2 may include an adhesive layer (e.g., DAF; not shown) which may help the second carrier substrate 2 to the upper molded portion 120D. The adhesive layer may be substantially similar to the adhesive layer used on the first carrier substrate 1.

FIG. 2K is a vertical cross-sectional view of an intermediate structure including the lower RDL structure 120A according to one or more embodiments. As illustrated in FIG. 2K, after the second carrier substrate 2 is placed on the upper molded portion 120D, the intermediate structure of FIG. 2J may be inverted and the first carrier substrate 1 may be detached from the lower molded portion 120B. The first carrier substrate 1 may be detached from the lower molded portion 120B, for example, by deactivating the adhesive layer (e.g., DAF; not shown) adhering the first carrier substrate 1 to the lower molded portion 120B. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

After the first carrier substrate 1 is detached from the lower molded portion 120B, a backside of the lower molded portion 120B including the lower molding material layer 127 may be planarized (e.g., by grinding, CMP, etc.) to expose a backside of the TIVs 123, a backside of the through vias 106 in the LSI die 101 and through vias 206 in the LRI dies 201. The lower RDL structure 120A may then be formed on the lower molded portion 120B. The lower RDL structure 120A may be formed in a manner substantially similar to the manner of forming the upper RDL structure 120C (e.g., see FIG. 2E and associated text).

After the lower RDL structure 120A is formed, the C4 bumps 121 may be formed on the lower RDL structure 120A. The C4 bumps 121 may include, for example, a metal pillar (e.g., copper pillar) formed, for example, by an electroplating process. Solder bumps may then be formed on the metal pillar. The solder may be formed on the metal pillar, for example, by one or more processes including ball mounting, electroplating, solder printing, solder immersion and solder injection.

FIG. 2L is a vertical cross-sectional view of an intermediate structure on a frame mount 300 according to one or more embodiments. After the C4 bumps 121 are formed on the lower RDL structure 120A, the intermediate structure may be inverted and placed on a frame mount 300. In particular, the C4 bumps 121 may contact an upper surface of the frame mount 300. The frame mount 300 may provide physical support to the intermediate structure and ensure that the intermediate structure is securely held in place during the fabrication process.

FIG. 2M is a vertical cross-sectional view of an intermediate structure after removing the second carrier substrate 2 according to one or more embodiments. The second carrier substrate 2 may be detached (e.g., debonded) from the upper molded portion 120D in a manner substantially similar to the manner in which the first carrier substrate 1 was detached from the lower molded portion 120B. In particular, the second carrier substrate 2 may be detached by deactivating the adhesive layer (e.g., DAF; not shown) adhering the second carrier substrate 2 to the upper molded portion 120D. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

FIG. 2N is a vertical cross-sectional view of an intermediate structure after remounting the intermediate structure on the frame mount 300 according to one or more embodiments. As illustrated in FIG. 2N, after the second carrier substrate 2 is detached, the intermediate structure may be inverted and remounted on the frame mount 300. In particular, the intermediate structure may be mounted on the frame mount 300 such that the upper molded portion 120D contacts an upper surface of the frame mount 300. The C4 bumps 121 may be cleaned to remove any adhesive material from the adhesive layer (e.g., DAF).

After the C4 bumps 121 are cleaned, a singulation process (e.g., dicing, sawing, etc.) may be performed. The singulation process may separate the package module 120 from surrounding wafer material and complete the formation of the package module 120.

FIG. 2O is a vertical cross-sectional view of an intermediate structure including the package module 120 on the package substrate 110 according to one or more embodiments. As illustrated in FIG. 2O, the openings 110o may be formed in the package substrate 110 prior to mounting the package module 120 on the package substrate 110. The openings 110o may be formed in package substrate 110, for example, using a mechanical drill, a computer numerical control (CNC) machine, a laser drill, or a punch/stamp machine. Other suitable methods may be used to form the openings 110o in the package substrate 110.

After the singulation process is performed, the package module 120 may be mounted on the package substrate 110. In at least one embodiment, an electromechanical PNP machine may be used to position the package module 120 over the package substrate 110. The electromechanical PNP machine may then lower the package module 120 onto the package substrate 110 so that the C4 bumps 121 contact the package substrate upper bonding pads 114a. A reflow process may then be performed to cause a reflow of the solder in the C4 bumps 121. The package module 120 may thereby be electrically coupled to the package substrate 110.

FIG. 2P is a vertical cross-sectional view of an intermediate structure including the package underfill layer 119 according to one or more embodiments. The package underfill layer 119 may be applied by depositing and/or injecting an epoxy-based polymeric material onto the package substrate 110. The epoxy-based polymeric material may be applied on the package substrate 110 and spread (e.g., by capillary action) under the package module 120 and around the C4 bumps 121. In at least one embodiment, the epoxy-based polymeric material may fill substantially all of the gaps between the package module 120 and the package substrate 110. The epoxy-based polymeric material may then be cured, for example, in a box oven for about 90 minutes at about 150° C. to provide the package underfill layer 119 with a sufficient stiffness and mechanical strength.

FIG. 2Q is a vertical cross-sectional view of an intermediate structure including the TIM layer 170 and adhesive layer 160 according to one or more embodiments. After the package underfill layer 119 has cured, the TIM layer 170 may be formed or placed on the package module 120. In at least one embodiment, a thermally conductive adhesive layer (not shown) may first be formed on the package module 120, and the TIM layer 170 may be adhered to the package module 120 by the thermally conductive adhesive layer.

The adhesive layer 160 may be formed on the upper surface of the package substrate 110. The adhesive layer 160 may be formed to have a shape substantially the as a shape of the package lid foot portion 130a. The adhesive layer 160 may be formed and patterned, for example, by any suitable dispensing technique.

FIG. 2R is a vertical cross-sectional view of an intermediate structure including the package lid 130 according to one or more embodiments. As illustrated in FIG. 2R, the openings 130o may be formed in the package lid plate portion 130p prior to mounting the package lid 130 on the package substrate 110. The openings 130o may be formed in package lid plate portion 130p, for example, using a mechanical drill, a computer numerical control (CNC) machine, a laser drill, or a punch/stamp machine. Other suitable methods may be used to form the openings 130o in the package lid plate portion 130p.

After the openings 130o have been formed in the package lid plate portion 130p, the package lid 130 may be positioned over the package substrate 110 using an electromechanical PNP machine. In particular, the package lid 130 may be positioned over the package substrate 110 so that the openings 130o in the package lid plate portion 130p are substantially aligned with the openings 110o in the package substrate 110, as illustrated by the dashed lines in FIG. 2R. The package lid 130 may then be lowered onto the package substrate 110 and pressed onto the TIM layer 170 and the adhesive layer 160 on the package substrate 110.

The package lid 130 may then be clamped together with package module 120 and the package substrate 110 for a period to allow the adhesive layer 160 to cure and form a secure bond between the package lid 130 and the package substrate 110. The clamping may be performed, for example, by using a heat clamp module. The heat clamp module may apply a uniform force across the upper surface of the package lid 130.

FIG. 2S is a vertical cross-sectional view of an intermediate structure including the fastening member 400 according to one or more embodiments. After the adhesive layer 160 has cured, the fastening member 400 may be attached to the intermediate structure so as to fasten the package lid plate portion 130p to the package substrate 110. In particular, as illustrated in FIG. 2S, the second end of the shank 414 including the threaded portion 414a may be inserted up into the opening 110o in the package substrate 110 and then through the opening 130o in the package lid plate portion 130p until at least a portion of the threaded portion 414a protrudes up out of the opening 130o. The nut 420 may then be connected to the threaded portion 414a until a tight connection is established. The nut 420 may be tightened enough to create a compressive force between the nut 420 and the bolt head 412 on the bottom of the package substrate 110. All of the nuts 420 should be tightened with the same amount of torque on all of the threaded portions 414a for all of the bolts 410 in the package structure 100. This may help to ensure that the package lid plate portion 130p remains substantially parallel with the package substrate 110, and that the compressive force is evenly distributed over the package module 120.

FIG. 2T is a vertical cross-sectional view of an intermediate structure including the solder balls 181 of the BGA according to one or more embodiments. After the adhesive layer 160 has adequately cured, the intermediate structure may be inverted and the solder balls 181 of the BGA may be formed on the board-side surface of the package substrate 110. The solder balls 181 may be formed, for example, by one or more processes including ball mounting, electroplating, solder printing, solder immersion and solder injection. The forming of the solder balls 181 may complete the formation of the package structure 100.

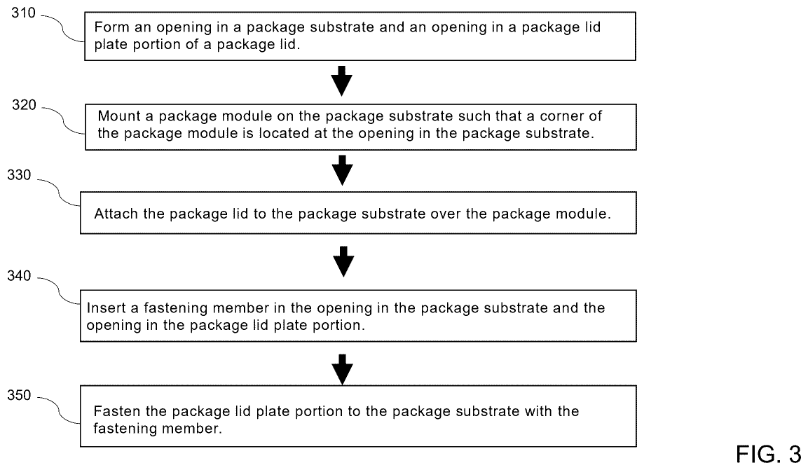

FIG. 3 is a flow chart illustrating a method of making the package structure 100 according to one or more embodiments. Step 310 includes forming an opening in a package substrate and an opening in a package lid plate portion of a package lid. Step 320 includes mounting a package module on the package substrate such that a corner of the package module is located at the opening in the package substrate. Step 330 includes attaching the package lid to the package substrate over the package module. Step 340 includes inserting a fastening member in the opening in the package substrate and the opening in the package lid plate portion. Step 350 includes fastening the package lid plate portion to the package substrate with the fastening member.

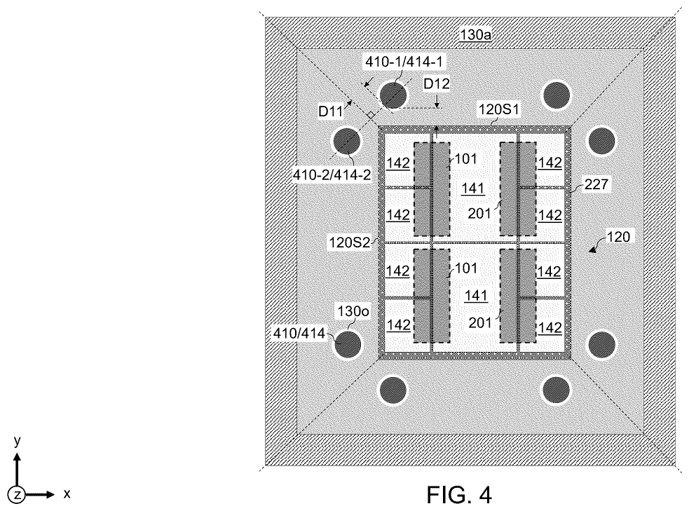

FIG. 4 is a top-down view of the package structure 100 having a first alternative configuration according to one or more embodiments. In FIG. 4, the package lid plate portion 130p, TIM layer 170, and nut 420 are omitted from FIG. 1D for ease of explanation. A location of the LSI die 101 and LRI die 201 beneath the semiconductor dies 140 are shown as shadows in FIG. 4.

As illustrated in FIG. 4, the package structure 100 may include a plurality of bolts 410 located at each corner of the plurality of corners of the package module 120. The plurality of bolts 410 may be located on opposing sides of the corner. In particular, the plurality of bolts 410 may be located on opposing sides of the diagonal line extending from the corner of the package module 120 to the inside corner of the package lid foot portion 130a. With this configuration, the risk of a high temperature causing warpage resulting in separation of the package lid plate portion 130p at the corner of the package module 120 may be further reduced as compared to the configuration of FIGS. 1A-1E.

The plurality of bolts 410 may include a first bolt 410-1 formed on a first side 120S1 of the package module 120 and a second bolt 410-2 formed on a second side 120S2 of the package module 120. The opening 130o in the package lid plate portion 130p may be located so that a shank 414-1 of the first bolt 410-1 is separated from the diagonal line by a distance D11 in a range from 1 cm to 2 cm. The opening 130o may also be located so that the shank 414-1 of the first bolt 410-1 is separated from the first sidewall 120S1 of the package module 120 (including the corner of the package module 120) by a distance D12 in a range from 1 cm to 2 cm.

As further illustrated in FIG. 4, the first bolt 410-1 and the second bolt 410-2 may be located on a line that is substantially perpendicular to the diagonal line extending from the corner of the package module 120 to the inner corner of the package lid foot portion 130a. The distance between the second bolt 410-2 and the diagonal line may be substantially equal to the distance between the first bolt 410-1 and the diagonal line. The distance between the second bolt 410-2 and the second side 120S2 of the package module 120 may be substantially equal to the distance between the first bolt 410-1 and the first side 120S1 of the package module 120.

In particular, the openings 130o in the package lid plate portion 130p may be located so that a shank 414-2 of the second bolt 410-2 is also separated from the diagonal line by the distance D11 in a range from 1 cm to 2 cm. The openings 130o may also be located so that the shank 414-2 of the second bolt 410-2 is separated from the second sidewall 120S2 of the package module 120 (including the corner of the package module) by the distance D12 in a range from 1 cm to 2 cm.

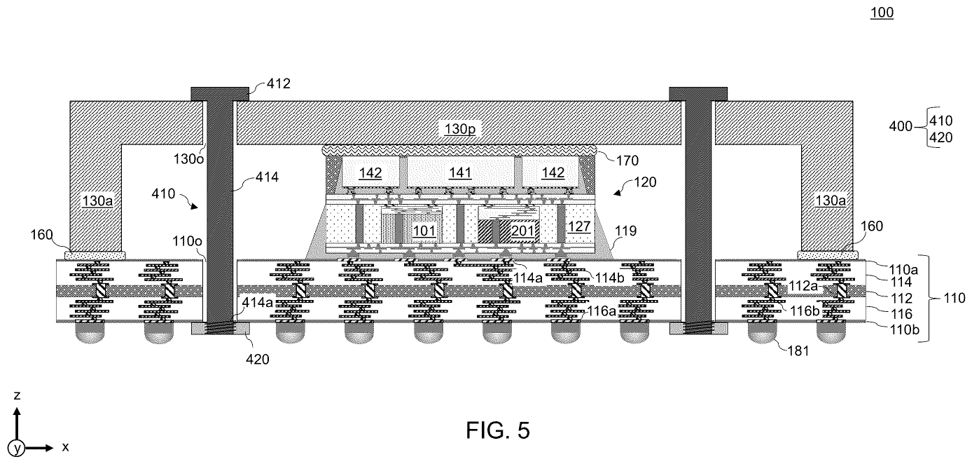

FIG. 5 is a vertical cross-sectional view of the package structure 100 having a second alternative configuration according to one or more embodiments. As illustrated in FIG. 5, in the second alternative configuration, the fastening member 400 may be inverted from its configuration in FIGS. 1A-1E. In particular, the bolt 410 may inserted in into the opening 130o of the package lid plate portion 130p so that the bolt head 412 is on the upper surface of the package lid plate portion 130p. The threaded portion 414a of the shank 414 may then extend out of the bottom of the opening 110o in the package substrate 110. The nut 420 may then be connected to the threaded portion 414a of the shank 414.

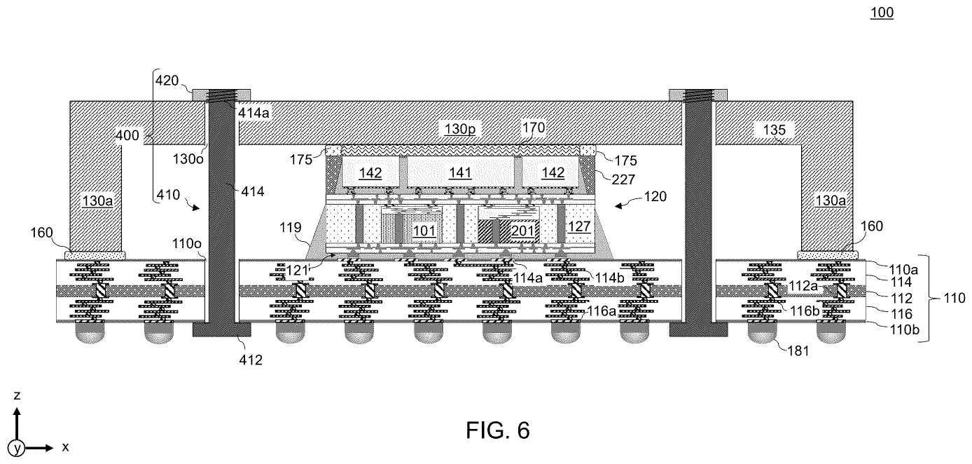

FIG. 6 is a vertical cross-sectional view of the package structure 100 having a third alternative configuration according to one or more embodiments. As illustrated in FIG. 5, in the third alternative configuration, a size of the TIM layer 170 may be reduced compared to a size of the TIM layer 170 in the configuration of FIGS. 1A-1E. In the third alternative configuration, an outer edge of the TIM layer 170 may be substantially aligned with an outermost edge of the semiconductor dies 140 in the package module 120.

The package module 100 may also include a thermal adhesive layer 175 on the upper surface of the package module 120 outside the TIM layer 170. The thermal adhesive layer 175 may be located on an upper surface of the upper molding material layer 227. The thermal adhesive layer 175 may be formed around an entire periphery of the TIM layer 175. With this configuration, the risk of a high temperature causing warpage resulting in separation of the package lid plate portion 130p may be further reduced as compared to the configuration of FIGS. 1A-1E.

The thermal adhesive layer 175 may have a high thermal conductivity, a high dielectric constant and a low CTE. The thermal adhesive layer 175 may include a base material (e.g., base polymer) such as an epoxy resin, silicone, etc. The thermal adhesive layer 175 may also include a filler in the base material to enhance thermal conductivity. The filler may include, for example, a ceramic material such as aluminum oxide, boron nitride or silicon carbide.

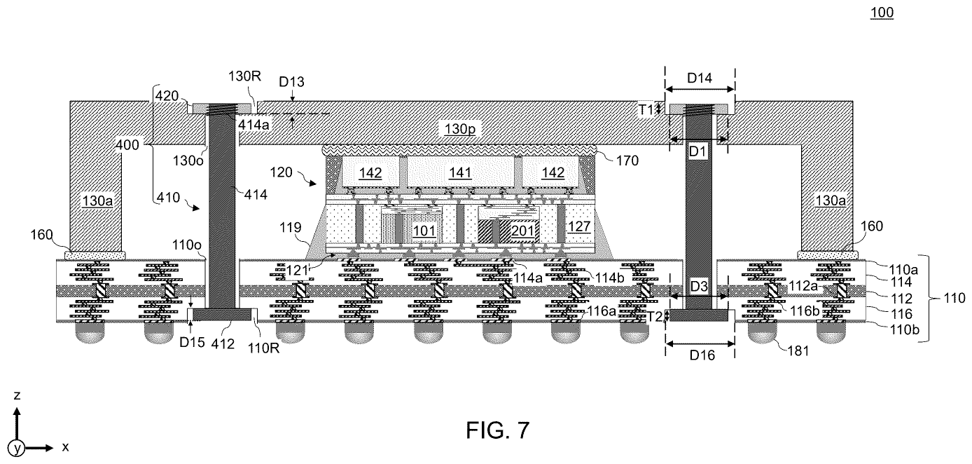

FIG. 7 is a vertical cross-sectional view of the package structure 100 having a fourth alternative configuration according to one or more embodiments. As illustrated in FIG. 7, in the fourth alternative configuration, the nut 410 may be located in a recessed portion 130R of the package lid plate portion 130p, and the bolt head 412 may be located in a recessed portion 110R of the package substrate 110.

The recessed portion 130R in the package lid plate portion 130p may have a shape in a top-down view substantially similar to a shape of the nut 420 in a top-down view. The recessed portion 130R in the package lid plate portion 130p may have a depth D13 substantially equal to or greater than a thickness T1 of the nut 420. In particular, the depth D13 of the recessed portion 130R may be in a range from 2 mm to 3 mm. The recessed portion 130R may also have a width D14 greater than a width D1 of the nut 420. In particular, the recessed portion 130R may also have a width D14 that is at least 20% greater than a width D1 of the nut 420. In at least one embodiment, the width D14 may be in a range from 8 mm to 12 mm.

The recessed portion 110R in the package substrate 110 may have a shape in a bottom-up view substantially similar to a shape of the bolt head 412 in a bottom-up view. The recessed portion 110R in the package substrate 110 may have a depth D15 substantially equal to or greater than a thickness T2 of the bolt head 412. In particular, the depth D15 of the recessed portion 110R may be in a range from 2 mm to 6 mm. The recessed portion 110R may also have a width D16 greater than a width D3 of the bolt head 412. In particular, the recessed portion 110R may also have a width D16 that is at least 20% greater than a width D3 of the bolt head 412. In at least one embodiment, the width D16 may be in a range from 8 mm to 12 mm.

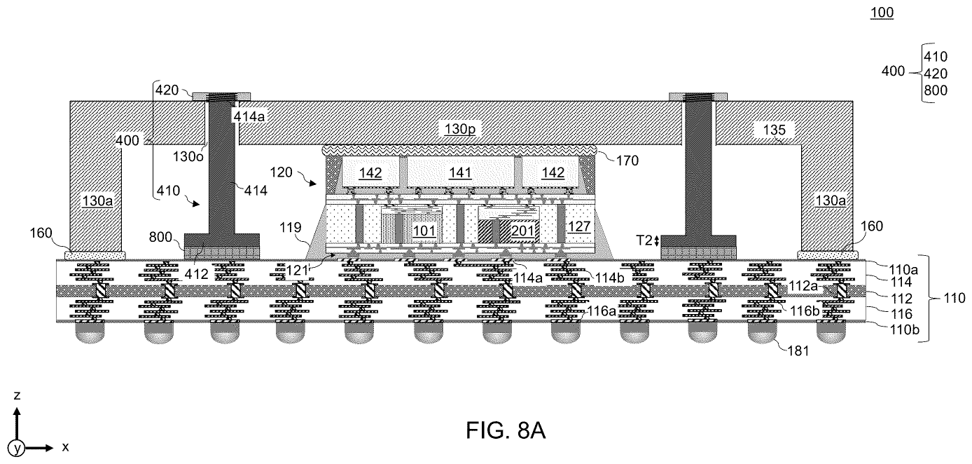

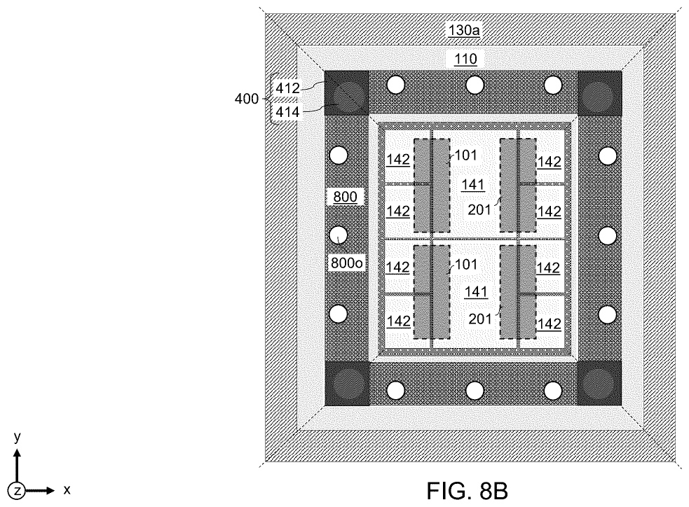

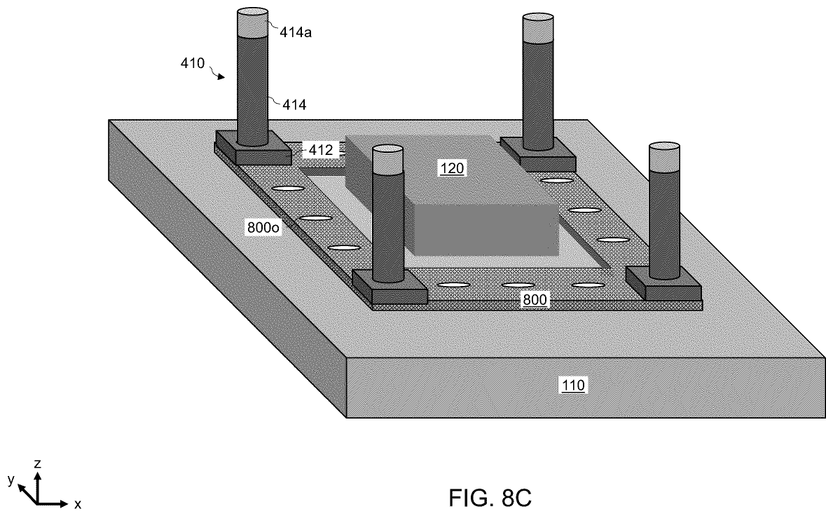

FIGS. 8A-8C are various views of the package structure 100 having a fifth alternative configuration according to one or more embodiments. FIG. 8A is a vertical cross-sectional view of the package structure 100 having the fifth alternative configuration according to one or more embodiments. FIG. 8B is a top-down view of the package structure 100 having the fifth alternative configuration according to one or more embodiments. FIG. 8C is a perspective view of the package structure 100 having the fifth alternative configuration according to one or more embodiments.

As illustrated in FIG. 8A, in the fifth alternative configuration, the fastening member 400 may include a bracket 800 in addition to the bolt 410 and nut 420. The bracket 800 may be fixed to the upper surface of the package substrate 100. The bracket 800 may be made of a rigid, thermally resistant material such as metal or a ceramic material. In at least one embodiment, the bracket 800 may include substantially the same material as the bolt 410. The bolt head 412 of the bolt 410 may be fixed to the bracket 800 so that an opening 110o in the package substrate 110 may be unnecessary. The bolt head 412 of the bolt 410 may be fixed to the bracket 800 by welding, epoxy adhesive, silicone adhesive, etc. The bracket 800 may have a thickness equal to or greater than the thickness T2 of the of bolt head 412.

Referring again to FIG. 8B, the package lid plate portion 130p, TIM layer 170, and nut 420 are omitted for ease of explanation. As illustrated in FIG. 8B, the bracket 800 may be formed continuously around the entire outer perimeter of the package module 120. In at least one embodiment, the bracket 800 may have a frame-shape. The corners of the bracket 800 may be substantially aligned with the corner of the package module 120 and the inner corner of the package lid foot portion 130a. In particular, a center of the corner of the bracket 800 may be substantially located on the diagonal line between the corner of the package module 120 and the inner corner of the package lid foot portion 130a. The bolt heads 412 of the bolts 410 may be mounted in the corners of the bracket 800 so as to be substantially located on the diagonal line.

The bracket 800 may also include a plurality of openings 800o between the bolts 410. The openings 800o may be formed through an entire thickness of the bracket 800. The bracket 800 may be attached to the upper surface of the package substrate 110. In particular, the bracket 800 may be attached to the upper surface of the package substrate 110 by an adhesive (not shown) such as an epoxy adhesive, silicone adhesive, etc. The adhesive may be formed in the openings 800o which may increase a strength of the adhesive bond between the bracket 800 and the upper surface of the package substrate 110.

As illustrated in FIG. 8C, the bolt head 412 of the bolt 410 may have a square shape and be substantially aligned with the corner of the bracket 800. The bolt head 412 may be attached to the bracket 800 so as to extend upward substantially perpendicular to the upper surface of the bracket 800 and substantially perpendicular to the upper surface of the package substrate 110.

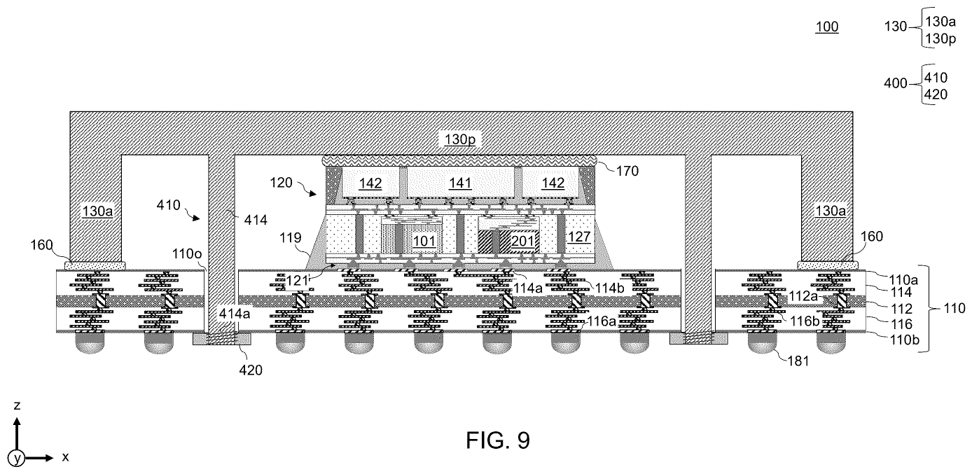

FIG. 9 is a vertical cross-sectional view of the package structure 100 having a sixth alternative configuration according to one or more embodiments. As illustrated in FIG. 9, in the sixth alternative configuration, the shank 414 of the bolt 410 may be integrally formed with the package lid plate portion 130p. The shank 414 including the threaded portion 414a of the bolt 410 may be formed together with the package lid plate portion 130p at the time of fabricating the package lid 130. The bolt 410 may therefore, be made of the same material as the package lid 130. The bolt head 412 of the bolt 410 and the opening 130o in the package lid plate portion 130p may be absent in the seventh configuration.

At the time of mounting the package lid 130 on the package substrate 110, the threaded portion 414a may be inserted into the opening 110o in the package substrate 110. The nut 420 may then be attached to the threaded portion 414a to secure the shank 414 of the bolt 410 to the package substrate 110.

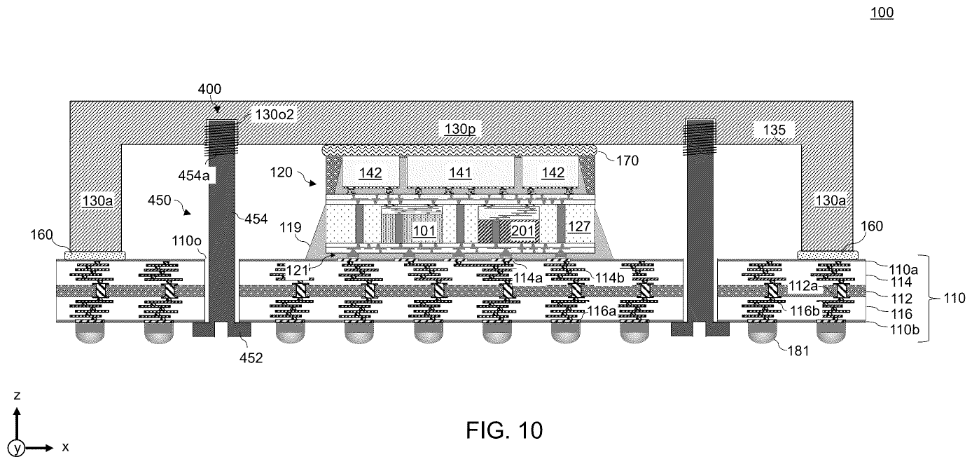

FIG. 10 is a vertical cross-sectional view of the package structure 100 having a seventh alternative configuration according to one or more embodiments. As illustrated in FIG. 10, in the seventh alternative configuration, the fastening member 400 may include a screw 450 instead of the bolt 410 and nut 420 combination. In addition, the opening 130o in the package lid plate portion 130p may be replaced with a threaded opening 130o2 having a threaded inner wall. The threaded opening 130o2 may or may not extend all the way through the package lid plate portion 130p.

The screw 450 may include a shank 454 and a screw head 452 attached to a first end of the shank 454. The screw head 454 may include, for example, an Allen head, machine head, hex head, Phillips head, etc. The shank 454 may include a threaded portion 454a at the second end of the shank 454 opposite the screw head 452.

The fastening member 400 including the screw 450 may fasten the package lid plate portion 130p to the package substrate 110 in a manner similar to the way the bolt 410 fastened the package lid plate portion 130p to the package substrate 110. In particular, at the time of mounting the package lid 130 on the package substrate 110, the shank 454 of the screw 450 may be inserted up into a bottom of the opening 110o of the package substrate 110. The shank 454 may be pushed up into the threaded opening 130o2 in the package lid plate portion 130p. The screw head 452 may then be rotated to cause the threads on the surface of the threaded portion 454a of the shank 454 to engage threads on the inner wall of the threaded opening 130o2. The shank 454 may thereby be securely fixed to the package lid plate portion 130p so that the package lid 130 is fastened to the package substrate 110.

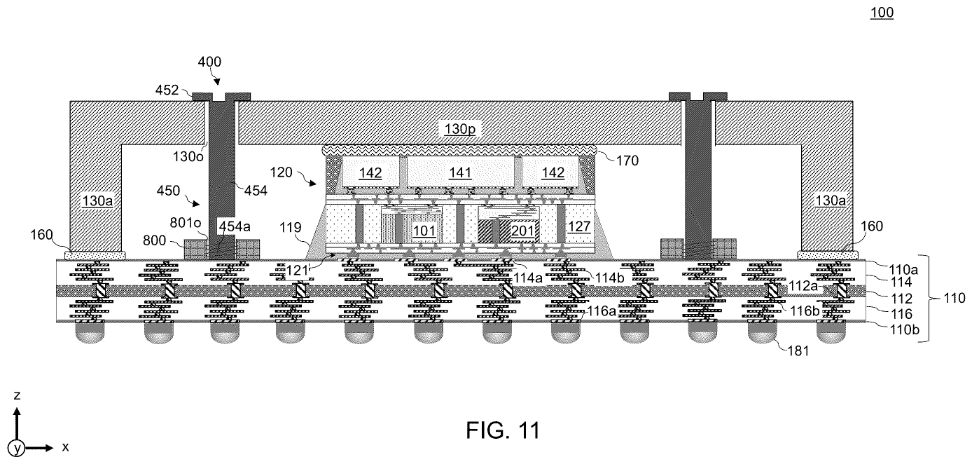

FIG. 11 is a vertical cross-sectional view of the package structure 100 having an eighth alternative configuration according to one or more embodiments. As illustrated in FIG. 11, in the eighth alternative configuration, the fastening member 400 may also include the screw 450 instead of the bolt 410 and nut 420 combination. The fastening member 400 may also include the bracket 800 as in the fifth alternative configuration. The bracket 800 may be fixed to the upper surface of the package substrate 110 by an adhesive (e.g., epoxy adhesive, silicone adhesive, etc.).

However, in the eighth alternative configuration, the bracket 800 may be different than the bracket 800 in the fifth alternative configuration. In particular, the bracket 800 in the eighth configuration may include a threaded opening 801o. The screw 450 may be connected to the bracket 800 in the threaded opening 801o. In particular, the shank 454 of the screw 450 may be inserted into the opening 130o of the package lid plate portion 130p. The shank 454 may be pushed down into the threaded opening 801o in the bracket 800. The screw head 452 may then be rotated to cause the threads on the surface of the threaded portion 454a of the shank 454 to engage threads on an inner wall of the threaded opening 801o. The shank 454 may thereby be securely fixed to the bracket 800. With this configuration of the package structure 100, the opening 110 in the package substrate 110 and the nut 420 may be unnecessary.

Referring to FIGS. 1A-11, a package structure 100 may include a package substrate 110, a package module 120 on the package substrate 110, a package lid 130 including a package lid plate portion 130p over the package module 120, and a package lid foot portion 130a connected to the package lid plate portion 130p and attached to the package substrate 110, and a fastening member 400 located at a corner of the package module 120 and configured to fasten the package lid plate portion 130p to the package substrate 110.

In one embodiment, the fastening member 400 may include a bolt 410 including a bolt head 412, and a shank 414 having a first end connected to the bolt head 412 and a second end including a threaded portion 414a. In one embodiment, the bolt 410 may be located on a line connecting a corner of the package lid foot portion 130a and the corner of the package module 120. In one embodiment, a distance D9 between the bolt 410 and the corner of the package module 120 may be less than a distance D10 between the bolt 410 and the corner of the package lid foot portion 130a. In one embodiment, the distance D10 between the bolt 410 and the corner of the package lid foot portion 130a may be at least 50% greater than the distance D9 between the bolt 410 and the corner of the package module 120. In one embodiment, the corner of the package module 120 may include a plurality of corners and the bolt 410 may include a plurality of bolts 410 located at the plurality of corners of the package module 120, respectively. In one embodiment, the bolt 410 may include a plurality of bolts 410 located on opposing sides of a line connecting a corner of the package lid foot portion 130a and the corner of the package module 120. In one embodiment, the fastening member 400 may further include a nut 420 connected to the threaded portion 414a at the second end of the shank 414. In one embodiment, the first end of the shank 414 may be in an opening 110o in the package substrate 110 and may be fixed to the package substrate 110 by the bolt head 412, and the second end of the shank 414 may be in an opening 130o in the package lid plate portion 130p and may be fixed to the package lid plate portion 130p by the nut 420. In one embodiment, the nut 420 may be located in a recessed portion 130R of the package lid plate portion 130p, and the bolt head 412 may be located in a recessed portion 110R of the package substrate 110. In one embodiment, the fastening member 400 may further include a bracket 800 attached to an upper surface of the package substrate 110 around the package module 120 and the bolt 410 may be connected to the bracket 800. In one embodiment, the package structure 100 may further include an adhesive layer around the package module 120, wherein the bracket 800 may be attached to the upper surface of the package substrate 110 by the adhesive layer. In one embodiment, a distance between the shank 414 of the bolt 410 and the corner of the package module 120 may be no more than 2 cm.

Referring again to FIGS. 1A-11, a method of making a package structure 100 may include forming an opening 110o in a package substrate 110 and an opening 130o in a package lid plate portion 130p of a package lid 130, mounting a package module 120 on the package substrate 110 such that a corner of the package module 120 may be located at the opening 110o in the package substrate 110, attaching the package lid 130 to the package substrate 110 over the package module 120, inserting a fastening member 400 in the opening 110o in the package substrate 110 and the opening 130o in the package lid plate portion 130p, and fastening the package lid plate portion 130p to the package substrate 110 with the fastening member 400.

In one embodiment, the fastening member 400 may include a bolt 410 including a shank 414, and the fastening of the package lid plate portion 130p to the package substrate 110 may include connecting a first end of the shank 414 to the package substrate 110 and connecting a second end of the shank 414 to the package lid plate portion 130p. In one embodiment, the attaching of the package lid 130 to the package substrate 110 may include attaching the package lid 130 to the package substrate 110 such that the opening 130o in the package lid plate portion 130p and the opening 110o in the package substrate 110 are substantially vertically aligned and are on a line connecting a corner of the package lid foot portion 130a and a corner of the package module 120. In one embodiment, the forming of the opening 110o in a package substrate 110 and the opening 130o in the package lid plate portion 130p may include forming a plurality of openings 110o in the package substrate 110 and a plurality of openings 130o in the package lid plate portion 130p, and the attaching of the package lid 130 to the package substrate 110 may include attaching the package lid 130 to the package substrate 110 such that an opening 130o of the plurality of openings 130o in the package lid plate portion 130p and an opening 110o of the plurality of openings 110o in the package substrate 110 are located on opposing sides of a line connecting a corner of the package lid foot portion 130a and the corner of the package module 120. In one embodiment, the bolt 410 may further include a bolt head 412 at the first end of the shank 414 and the fastening of the package lid plate portion 130p to the package substrate 110 may include attaching a nut 420 to the second end of the shank 414 such that the bolt head 412 connects the first end of the shank 414 to the package substrate 110 and the nut 420 connects the second end of the shank 414 to the package lid plate portion 130p. In one embodiment, the fastening of the package lid plate portion 130p to the package substrate 110 may include fastening the package lid plate portion 130p to the package substrate 110 such that the nut 420 may be in a recessed portion 130R of the package lid plate portion 130p and the bolt head 412 may be in a recessed portion 110R of the package substrate 110.

Referring again to FIGS. 1A-11, a package structure 100 may include a package substrate 110, a package module 120 on the package substrate 110, a thermal adhesive 175 on the package module 120, a package lid 130 including a package lid plate portion 130p over the package module 120 and attached to the package module 120 by the thermal adhesive 175, and a package lid foot portion 130a connected to the package lid plate portion 130p and attached to the package substrate 110, and a fastening member 400 extending through the package lid plate portion 130p and the package substrate 110.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a package module on the package substrate;
a package lid comprising:
a package lid plate portion over the package module; and
a package lid foot portion connected to the package lid plate portion and attached to the package substrate; and
a fastening member located at a corner of the package module and configured to fasten the package lid plate portion to the package substrate.

2. The package structure of claim 1, wherein the fastening member includes a bolt comprising:
a bolt head; and
a shank having a first end connected to the bolt head and a second end including a threaded portion.

3. The package structure of claim 2, wherein the bolt is located on a line connecting a corner of the package lid foot portion and the corner of the package module.

4. The package structure of claim 3, wherein a distance between the bolt and the corner of the package module is less than a distance between the bolt and the corner of the package lid foot portion.

5. The package structure of claim 4, wherein the distance between the bolt and the corner of the package lid foot portion is at least 50% greater than the distance between the bolt and the corner of the package module.

6. The package structure of claim 2, wherein the corner of the package module comprises a plurality of corners and the bolt comprises a plurality of bolts located at the plurality of corners of the package module, respectively.

7. The package structure of claim 2, wherein the bolt comprises a plurality of bolts located on opposing sides of a line connecting a corner of the package lid foot portion and the corner of the package module.

8. The package structure of claim 2, wherein the fastening member further comprises a nut connected to the threaded portion at the second end of the shank.

9. The package structure of claim 8, wherein the first end of the shank is in an opening in the package substrate and is fixed to the package substrate by the bolt head, and the second end of the shank is in an opening in the package lid plate portion and is fixed to the package lid plate portion by the nut.

10. The package structure of claim 9, wherein the nut is located in a recessed portion of the package lid plate portion, and the bolt head is located in a recessed portion of the package substrate.

11. The package structure of claim 2, wherein the fastening member further comprises a bracket attached to an upper surface of the package substrate around the package module and the bolt is connected to the bracket.

12. The package structure of claim 11, further comprising:
an adhesive layer around the package module, wherein the bracket is attached to the upper surface of the package substrate by the adhesive layer.

13. The package structure of claim 2, wherein a distance between the shank of the bolt and the corner of the package module is no more than 2 cm.

14. A method of making a package structure, the method comprising:
forming an opening in a package substrate and an opening in a package lid plate portion of a package lid;
mounting a package module on the package substrate such that a corner of the package module is located at the opening in the package substrate;
attaching the package lid to the package substrate over the package module;
inserting a fastening member in the opening in the package substrate and the opening in the package lid plate portion; and
fastening the package lid plate portion to the package substrate with the fastening member.

15. The method of making the package structure of claim 14, wherein the fastening member comprises a bolt including a shank, and the fastening of the package lid plate portion to the package substrate comprises connecting a first end of the shank to the package substrate and connecting a second end of the shank to the package lid plate portion.

16. The method of making the package structure of claim 15, wherein the attaching of the package lid to the package substrate comprises attaching the package lid to the package substrate such that the opening in the package lid plate portion and the opening in the package substrate are substantially vertically aligned and are on a line connecting a corner of a package lid foot portion and a corner of the package module.

17. The method of making the package structure of claim 15, wherein the forming of the opening in the package substrate and the opening in the package lid plate portion comprises forming a plurality of openings in the package substrate and a plurality of openings in the package lid plate portion, and the attaching of the package lid to the package substrate comprises attaching the package lid to the package substrate such that an opening of the plurality of openings in the package lid plate portion and an opening of the plurality of openings in the package substrate are located on opposing sides of a line connecting a corner of a package lid foot portion and the corner of the package module.

18. The method of making the package structure of claim 15, wherein the bolt further comprises a bolt head at the first end of the shank and the fastening of the package lid plate portion to the package substrate comprises attaching a nut to the second end of the shank such that the bolt head connects the first end of the shank to the package substrate and the nut connects the second end of the shank to the package lid plate portion.

19. The method of making the package structure of claim 18, wherein the fastening of the package lid plate portion to the package substrate comprises fastening the package lid plate portion to the package substrate such that the nut is in a recessed portion of the package lid plate portion and the bolt head is in a recessed portion of the package substrate.

20. A package structure, comprising:
a package substrate;
a package module on the package substrate;
a thermal adhesive on the package module;
a package lid comprising:
a package lid plate portion over the package module and attached to the package module by the thermal adhesive; and
a package lid foot portion connected to the package lid plate portion and attached to the package substrate; and
a fastening member extending through the package lid plate portion and the package substrate.
